(19) United States
(12) Patent Application Publication
(10) Pub. No.: US 2024/0292630 A1
(43) Pub. Date: Aug. 29, 2024

(54) MEMORY DEVICES HAVING ADJACENT MEMORY CELLS WITH MITIGATED DISTURB RISK

(71) Applicant: Micron Technology, Inc., Boise, ID (US)

(72) Inventors: Riccardo Pazzocco, Verona (IT); Marcello Mariani, Milano (IT); Giorgio Servalli, Fara Gera d'Adda (IT)

(21) Appl. No.: 18/584,470

(22) Filed: Feb. 22, 2024

Related U.S. Application Data
(60) Provisional application No. 63/448,162, filed on Feb. 24, 2023.

(51) Int. Cl. H10B 53/30; H01L 21/28; H01L 29/51; H01L 29/66; H01L 29/78; H10B 51/10; H10B 51/30; H10B 53/10

(52) U.S. Cl. CPC H10B 53/30; H01L 29/40111; H01L 29/516; H01L 29/6684; H01L 29/78391; H10B 51/10; H10B 51/30; H10B 53/10

(57) ABSTRACT

A variety of applications can include apparatus having a memory device with ferroelectric capacitors as storage structures in memory cells. The ferroelectric capacitors can be arranged vertically from a region of access transistors of the memory cells with the bottom electrodes of the ferroelectric capacitors arranged above and coupled to the access transistors. The bottom electrodes can be separated from the top electrodes of the ferroelectric capacitors by ferroelectric material. The bottom electrodes of ferroelectric capacitors of adjacent memory cells can be separated by a low-k dielectric material.

### PRIORITY APPLICATION

This application claims the benefit of priority to U.S. Provisional Application Ser. No. 63/448,162, filed Feb. 24, 2023, which is incorporated herein by reference in its entirety.

### FIELD OF THE DISCLOSURE

Embodiments of the disclosure relate generally to electronic devices and, more specifically, to memory devices.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices and other electronic devices can be improved by enhancements to the structure and fabrication of storage units in the memory devices.

### BRIEF DESCRIPTION OF THE DRAWINGS

The drawings, which are not necessarily drawn to scale, illustrate generally, by way of example, but not by way of limitation, various embodiments discussed in the present document.

FIGS. 1A-3B illustrate processed structures in an example process flow to form ferroelectric capacitors of memory cells on and extending vertically from access transistors of the memory cells, according to various embodiments.

FIGS. 4A-6B illustrate processed structures, after forming the processed structures of FIGS. 3A-3B, in an example proces flow to form ferroelectric capacitors of memory cells on and extending vertically from access transistors of the memory cells, according to various embodiments.

FIGS. 7A-9B illustrate processed structures, after forming the processed structures of FIGS. 3A-3B, in another example proces flow to form ferroelectric capacitors of memory cells on and extending vertically from access transistors for the memory cells, according to various embodiments.

FIG. 10 is a flow diagram of features of an example method of forming components of a memory device, according to various embodiments.

FIG. 11 is a schematic of an example memory device that can include an architecture having a memory array, where a memory cell includes a capacitor structure arranged as a storage unit of the memory cell of a memory device, according to various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments can be utilized, and structural, logical, mechanical, and electrical changes can be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

In memory devices having memory cells that use capacitors or capacitor-like structures as storage elements, a memory cell can include a capacitor as a storage element with the capacitor having a plate coupled to a transistor and another plate coupled to a reference line, referred to herein as a plate line (PL). The transistor of the memory cell can be a switching unit to the capacitor, with the transistor coupled to an access line (WL), for example a word line, and coupled to a digit line (DL), for example a bit line. The PL can couple the respective plate to a reference, such as system supply voltage (VSS), or to a plate line voltage (VPL) for a memory cell sense operation. In a ferroelectric RAM (FeRAM), a ferroelectric capacitor in each memory can be used as a storage device. A FeRAM, as a non-volatile memory, can maintain a stored logic state for extended periods of time even in the absence of an external power source. DRAMs can lose their stored state over time unless the DRAMS are periodically refreshed by an external power source.

A FeRAM can use similar device architectures as volatile memory, such as a DRAM architecture, but have non-volatile properties due to the use of a ferroelectric capacitor as a storage device. A ferroelectric memory cell can include a capacitor with a ferroelectric as the insulating material, where the ferroelectric has non-linear polarization properties, which are characterized by a spontaneous electric polarization that includes a voltage hysteresis. A ferroelectric maintains a non-zero electric polarization in the absence of an electric field such that different levels of charge of a ferroelectric capacitor can represent different logic states. A ferroelectric memory cell can be written by applying a voltage across the ferroelectric capacitor. Due to the ferroelectric between the plates of the capacitor of the ferroelectric memory cell, activation of the ferroelectric memory cell can be made in a two-sequence operation of sensing and precharge. Biasing the PL can result in a voltage difference across capacitor, which voltage difference is the difference between the voltage on the plate, coupled to the PL, and the voltage on DL. In the sensing operation, the voltage on the PL can be raised followed by raising the voltage on the access line to the selected ferroelectric memory cell, where the voltage can be lowered back during the sensing operation while maintaining the voltage of the access line. During the precharge, with the PL maintained in the base line state and the access line maintained in the selected state, the voltage on the digit line can be set to the logic state. The voltage on the DL can be lowered prior to removal of the select voltage on the access line.

The memory cells can be arranged in a memory array arranged as subarrays, where the plates of capacitors in each subarray are coupled to the PL assigned to the subarray, effectively defining a plate for the subarray. Whenever voltage of the PL to a memory cell moves, such as to a higher level from a lower level or to the lower level from the higher level, the voltage of the DL corresponding to the PL should follow the movement of the voltage on the PL to avoid a disturb voltage across memory cells on a selected WL and unselected DL. A disturb voltage to a memory cell is a voltage to which the memory cell is exposed, when nearby memory cells are accessed, that can affect data stored in the memory cell.

Architecutres for FeRAMs can include memory cells with each memory cell having an access transistor and a ferroelectric capacitor as a storage component arranged with the ferroelectric capacitor on and extending vertically from the access transistor. The ferroelectric capacitor has a bottom electrode separated by a top electrode by a ferroelectric material with the bottom electrode closest to the access transistor. In efforts to increase the memory capacity of such a FeRAM, the distances between bottom electrodes tend to be decreased. Typically, silicon dioxide or high-k dielectrics are placed between bottom electrodes of adjacent cells, which can lead to an increased disturb risk. Herein, a high-k material is a material that has a dielectric constant greater than the dielectric constant of silicon dioxide (3.9). Theoretical simulations indicate that bottom-electrode-to-bottom-electrode distance should be higher than ten nanometers to avoid large disturb issues, when using silicon dioxide or high-k dielectrics as separating insulators.

In various embodiments, a low-k material can be used between bottom electrodes of adjacent memory cells to limit disturb limitations. Herein, a low-k material is a material that has a dielectric constant less than the dielectric constant of silicon dioxide. The low-k material can have a dielectric constant equal to or less than 3.5. Low-k integration allows relaxation of the ten nanometer constraint and, consequently, process tolerances. Low-k integration can include a bottom-electrode-to-bottom-electrode distance equal to or less than 10 nanometers.

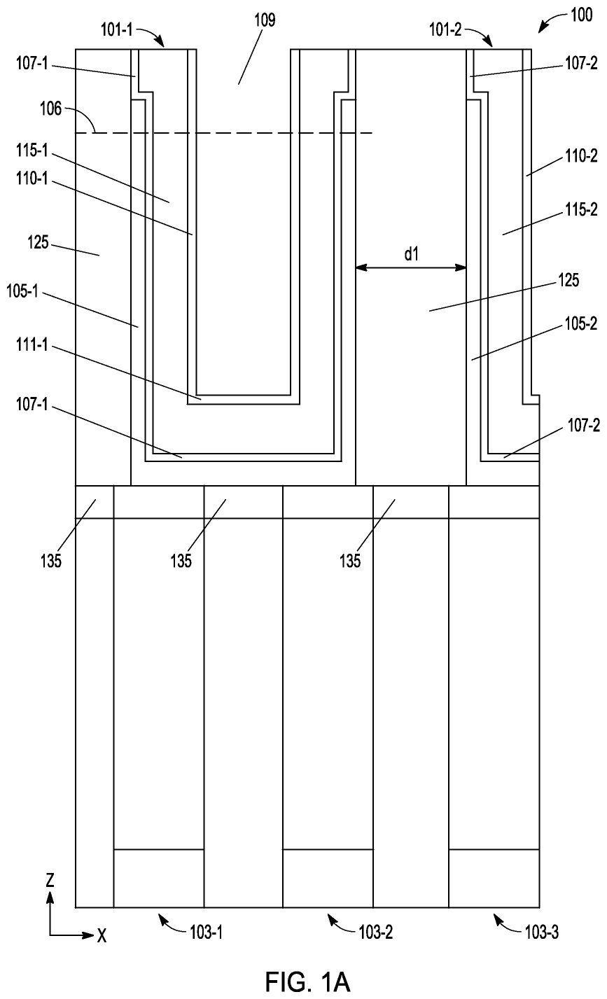

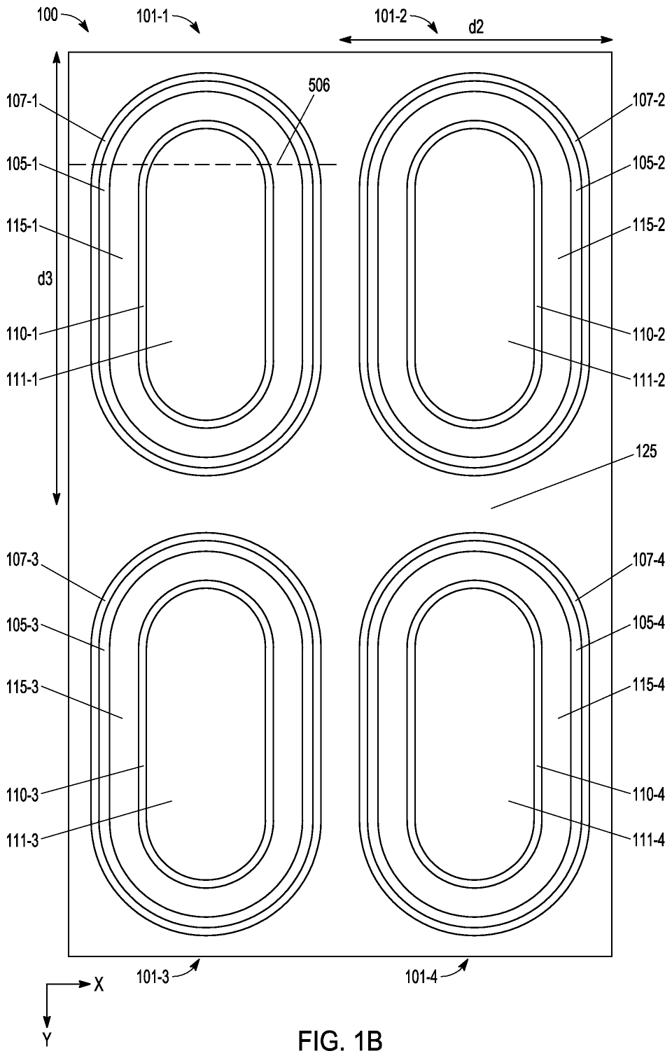

FIGS. 1A-3B illustrate processed structures in an example process flow to form ferroelectric capacitors of memory cells on and extending from access transistors of the memory cells. Though a limited number of components are shown in these figures and subsequent figures, formation of such memory cells can be extended to the number of memory cells for the desired memory device. FIGS. 1A-1B illustrate a structure 100 after initial processing to form ferroelectric capacitors on and extending vertically from the respective access transistors for forming memory cells. FIG. 1A is a cross-sectional view along dashed line 106 of FIG. 1B. In the cross-sctional view of FIG. 1A, portions of elements for ferroelectrics capacitors are being formed in container structures that are positioned on and extend vertically from a region containing transistors, such as transistors 103-1, 103-2, and 103-3. Transistors 103-1, 103-2, and 103-3 can be, but are not limited to, thin film transistors (TFTs).

FIG. 1A illustrates initial formation of ferroelectric capacitors in a container structure 101-1 on and extending vertically from transistors 103-1 and 103-2 and in container structure 101-2 in a region on and extending from transistor 103-3. Material for a bottom electrode 105-1 has been formed from a level at the tops of isolation regions 135, with a horizontal base and vertical walls from the horizontal base. Material for a leaker 107-1 has been formed on the material for a bottom elecrode. A leaker is a structure electrically coupling a bottom electrode to a plate to the ferroelectric capacitor to discharge at least a portion of excess charge from the bottom electrode to the plate. Ferroelectric material 115-1 has been formed on leaker 107-1. Material for a top electrode 110-1 has been formed on ferroelectric material 115-1. Material for a top electrode 110-1 has been formed on ferroelectric material 115-1, with a horizontal base 111-1 of the material for top electrode 110-1 on a horizontal portion of ferroelectric material 115-1. Vertical walls for material for a top electrode 110-1 have been formed with an appropriate thickness to form opening 109, which opening is to be used in further processing.

In this process flow, the deposited material for bottom electrode 105-1 of container structure 101-1 for adjacent memory cells of container structure 101-1 is not separated before deposition of ferroelectric material 115-1 and deposition of the material for top electrode 110-1. A deposition of relatively thin material for top electrode 110-1 allows for protection of ferroelectric material 115-1 from subsequent processing. Deposition of ferroelectric material 115-1 and the material for top electrode 110-1 on a continuous material for bottom electrode 105-1 decreases risk of ferroelectric phase instability as it guarantees proper top electrode-induced stress in a container structure.

Components of ferroelectric capacitors in container structure 101-2 can be formed similarly to the components of ferroelectric capacitors from transistors 103-1 and 103-2 in container structure 101-1. The components in container structure 101-2, and components of other similar container structures, can be formed when forming the components in in container structure 101-2.

Material for a bottom elecrode 105-2 has been formed from a level at the tops of isolation regions 135, with a horizontal base and vertical walls from the horizontal base. Material for a leaker 107-2 has been formed on the material for a bottom elecrode 105-2. Ferroelectric material 115-2 has been formed on leaker 107-2. Material for a top electrode 110-2 has been formed on ferroelectric material 115-2. Material for a top electrode 110-2 has been formed on ferroelectric material 115-2, with a horizontal base on a horizontal portion of ferroelectric material 115-1, similar to horizontal base 111-1 of material for top electrode 110-1 on a horizontal portion of ferroelectric material 115-1. Vertical walls for material for a top electrode 110-2 have been formed with an appropriate thickness to form an opening similar to opening 109, which opening is to be used in further processing.

Material for bottom electrode 105-1 in container structure 101-1 is separated from material for bottom electrode 105-2 in container 101-2 by a dielectric material 125. The distance d1 that separates bottom electrode 105-1 from material for bottom electrode 105-2 can be less than or equal to twelve nanometers. Other containers can be separated from adajcent containers by distance d1. In various embodiments, d1 can be less than or equal to ten nanometers.

FIG. 1B is a top view of structure 100 of FIG. 1A from the level of dashed line 106 of FIG. 1A. This top view shows container structures 101-1 and 101-2 of FIG. 1A along with container structures 101-3 and 101-4, where these container structures are separated by dielectric material 125. Though four container structures are shown in FIG. 1B, a memory device structured using such container structures can be implemented with significantly more container structures depending on the capacity of the memory device being fabricated. Each container structure can be structured with the same horizontal footprint defined by distance d2 and distance d3. A non-limiting example of distances d2 and d3 can be forty-eight nanometers and 76 nanometers, respectively. Each of containers 101-1, 101-2, 101-3, and 101-4 can include the same components.

For container structure 101-1, a relationship of leaker 107-1 to material for bottom electrode 105-1 is shown at this point in the fabrication procedure. The relationship of the material for bottom electrode 105-1 to ferroelectric material 115-1 and to the material for top electrode 110-1 is shown. Also indicated is the relationship of horizontal base 111-1 of the material for top electrode 110-1 to the material for top electrode 110-1.

For container structure 101-2, a relationship of leaker 107-2 to material for bottom electrode 105-2 is shown at this point in the fabrication procedure. The relationship of the material for bottom electrode 105-2 to ferroelectric material 115-2 and to the material for top electrode 110-2 is shown. Also indicated is the relationship of horizontal base 111-2 of the material for top electrode 110-2 to the material for top electrode 110-2.

For container structure 101-3, a relationship of a leaker 107-3 to material for a bottom electrode 105-3 is shown at this point in the fabrication procedure. The relationship of the material for bottom electrode 105-3 to a ferroelectric material 115-3 and to a material for top electrode 110-3 is shown. Also indicated is the relationship of a horizontal base 111-3 of the material for top electrode 110-3 to the material for top electrode 110-3.

For container structure 101-4, a relationship of a leaker 107-4 to material for a bottom electrode 105-4 is shown at this point in the fabrication procedure. The relationship of the material for bottom electrode 105-4 to a ferroelectric material 115-4 and to a material for top electrode 110-4 is shown. Also indicated is the relationship of a horizontal base 111-4 of the material for top electrode 110-4 to the material for top electrode 110-4.

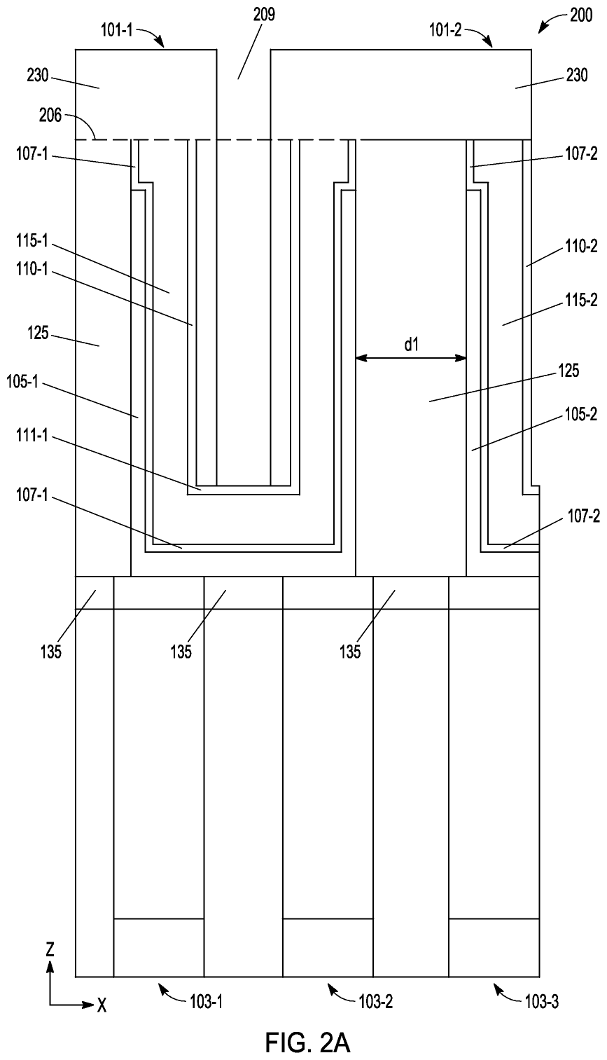

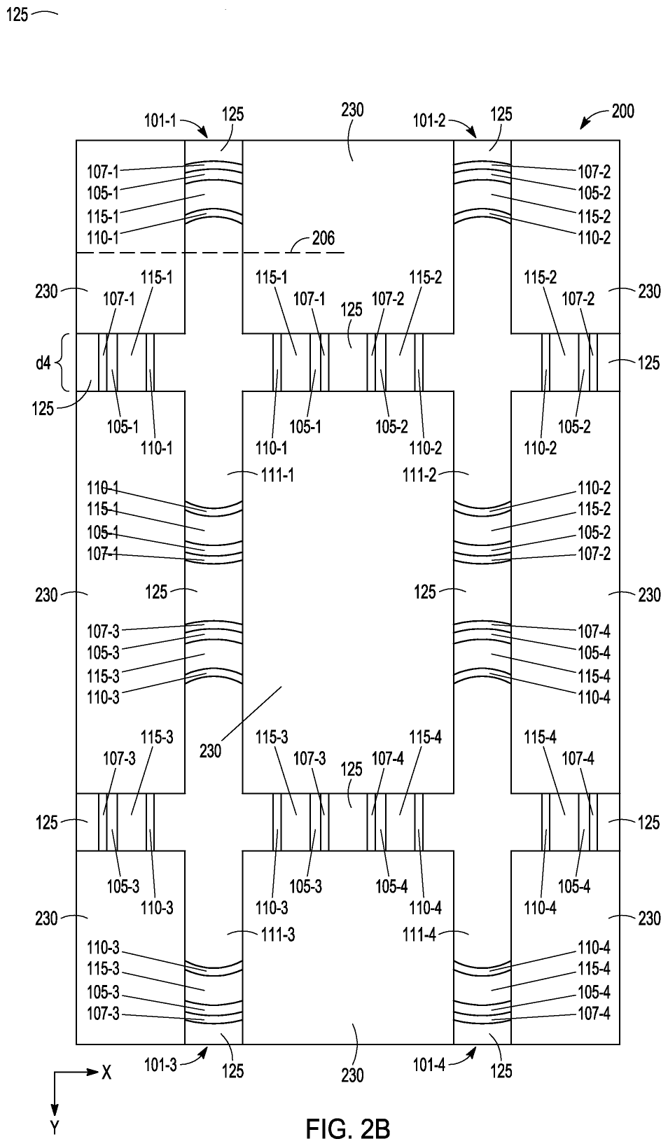

FIG. 2A shows a cross-sectional view of a structure 200 after processing structure 100 of FIGS. 1A-1B and is a cross-sectional view along dashed line 206 of FIG. 2B. Container patterning has been been initiated. A photoresist 230 has been formed on a top surface of structure 100 and on the vertical material for top electrode 110-1. Photoresist 230 protects sidewalls of the material for top electrode 110-1 in subsequent processing. Opening 109 has been reduced to an opening 209.

FIG. 2B is a top view of structure 200 of FIG. 2A from the level of dashed line 206 of FIG. 2A. This top view shows container structures 101-1 and 101-2 of FIG. 2A along with container structures 101-3 and 101-4, where these container structures are separated by dielectric material 125. This top view indicates a distance d4 of components of capacitors being fabricated for further processing. Distance d4 can be, but is not limited to, ten nanometers. The components of container structures 101-2, 101-3, and 101-4 have been processed in the same manner as the components of container structure 101-1.

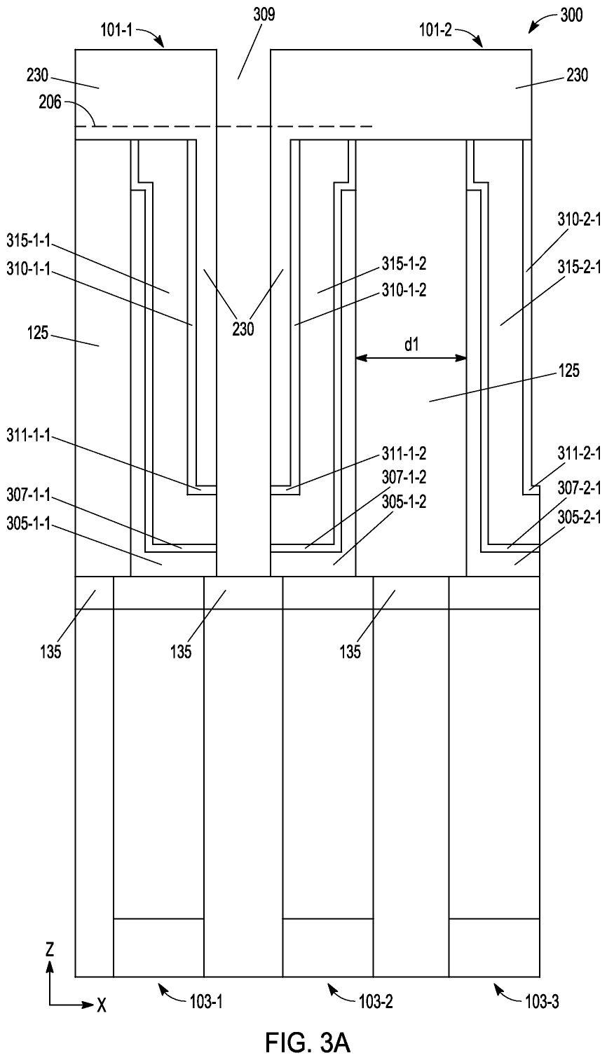

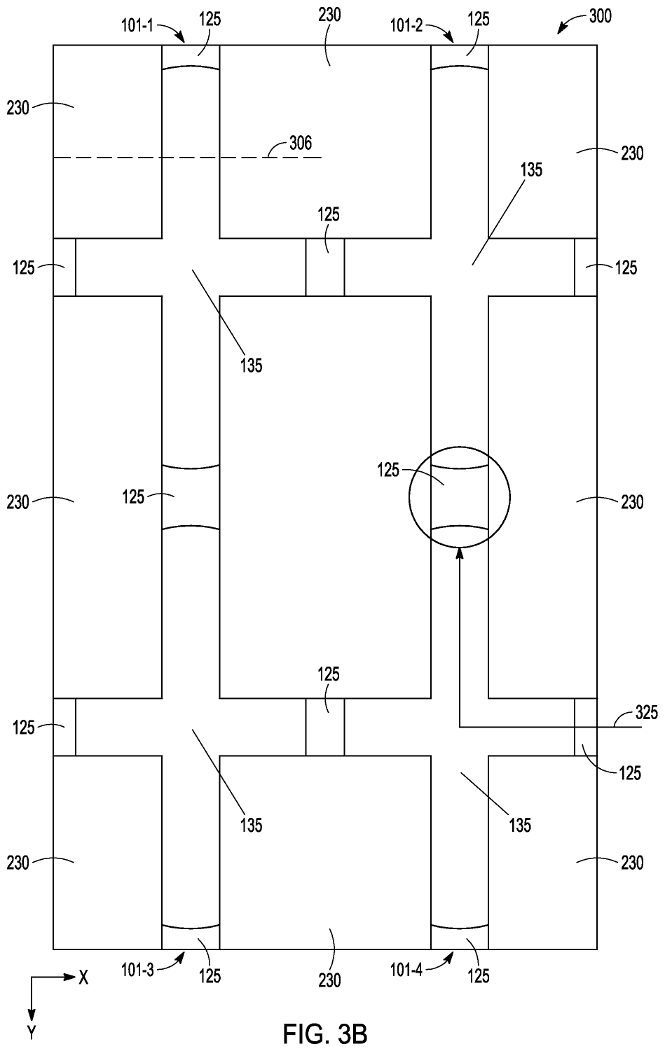

FIG. 3A shows a cross-sectional view of a structure 300 after processing structure 200 of FIGS. 2A-2B and is a cross-sectional view along dashed line 306 of FIG. 3B. Horizontal base 111-1 of the material for top electrode 110-1 has been partially removed using the opening 209 of structure 200. In addition, portions of ferroelectric material 115 below horizontal base 111-1, portions of leaker 107-1 below horizontal base 111-1, and portions of the material for bottom electrode 105-1 below horizontal base 111-1 have been removed. The removal of these portions extends opening 209 of structure 200 to a top level of the tops of isolation regions 135, forming opening 309. An etch can be performed on these materials to separate the material for bottom electrode 105-1 and other materal components of adjacent memory cells being formed in container structure 101-1. The etching process, forming opening 309, allows for subsequent low-k material deposition. To not remove dielectric material 125 between adjacent container structures, a selective etch can be used. The selective etching process can include, but is not limited to, one or more dry etching procedures. Selective etching is a process in which one or more materials are removed from a structure, while one or more other materials remain in the structure with no or little removal. Selective etching can depend on the material to be etched, the material not to be etched, the etchant employed, and the method for etching. Types of etching can include wet etching and dry etching, where each of these two basic methods can include a number of different etching procedures. In addtion, conventional masking techniques, providing protective regions in the processing, can be used in removal of selected regions.

The etching process has separated regions of container structures 101-1 into multiple portions for forming ferroelectric capacitors for memory cells in container structure 101-1. The removal process has separated material for the bottom electrode 105-1 in container structure 101-1 into material for a bottom electrode 305-1-1 and material for a bottom electrode 305-1-2, both new bottom electrode structures in container structure 101-1. The removal process has separated material for the leaker 107-1 in container structure 101-1 into a material for a leaker 307-1-1 and a material for a leaker 307-1-2, both new leaker structures in container structure 101-1. The removal process has separated ferroelectric material 115-1 in container structure 101-1 into a ferroelectric material 315-1-1 and a ferroelectric material 315-1-2, both new ferroelectric structures in container structure 101-1. The removal process has separated material for the material for a top electrode 110-1 into a material for a top electrode 310-1-1 and a material for a top electrode 310-1-2, both new top electrode structures in container structure 101-1. The removal process has separated horizontal base 111-1 of the material for top electrode 110-1 into a horizontal base 311-1-1 for top electrode 310-1-1 and a horizontal base 311-1-2 for a top electrode 310-1-2, both new horizontal base structures in container structure 101-1. The material for bottom electrode 305-1-1, material for leaker 307-1-1, ferroelectric material 315-1-1, and material for top electrode 310-1-1 in container structure 101-1 are being formed coupled to transistor 103-1 to form a memory cell. The material for bottom electrode 305-1-2, material for leaker 307-1-2, ferroelectric material 315-1-2, and material for top electrode 310-1-2 in container structure 101-1 are being formed coupled to transistor 103-2 to form another memory cell.

The material in the other containers 101-2, 101-3, and 101-4 have been processed in the same manner as the material in container structure 101-1. For example, FIG. 3A shows horizontal base 311-2-1 for a top electrode 310-2-1 and shows the material for bottom electrode 305-2-1, material for leaker 307-2-1, ferroelectric material 315-2-1, and material for top electrode 310-2-1 in container structure 101-2 being formed coupled to transistor 103-3 to form a memory cell.

FIG. 3B is a top view of structure 300 of FIG. 3A from the level of dashed line 306 of FIG. 3A. This top view shows container structures 101-1 and 101-2 of FIG. 3A along with container structures 101-3 and 101-4. FIG. 3B further demonstrates the result of the etch through horizontal bottoms of the materials for top electrodes to the top level of the tops of isolation regions 135. As can be seen from this top view, for each of container structures 101-1, 101-2, 101-3, and 101-4, the etching processing has generated four regions in each of these container structures to form four ferroelectric capacitiors for four memory cells, with each memory cell having an access transistor.

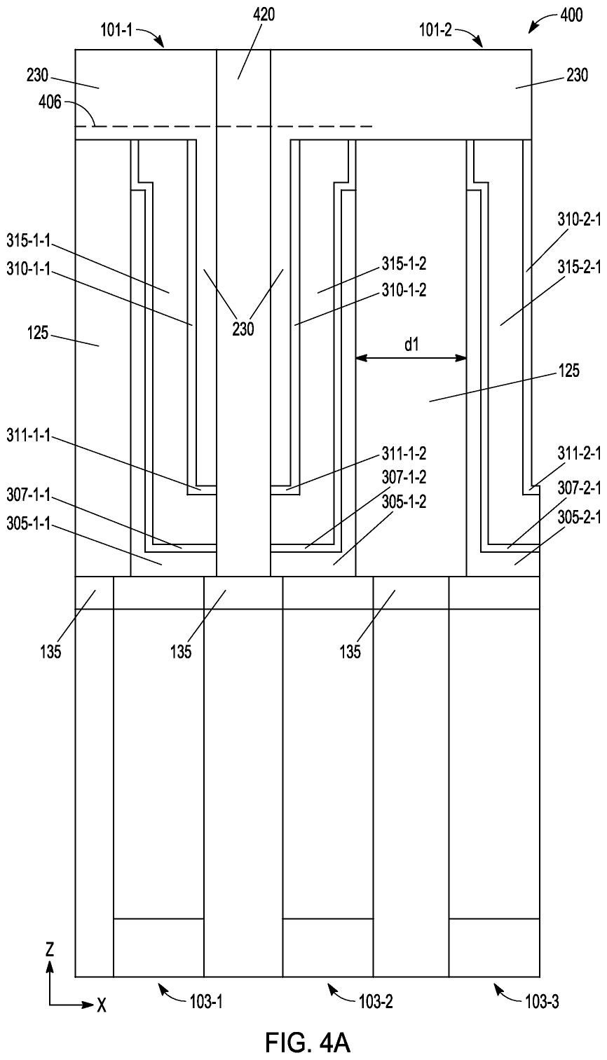

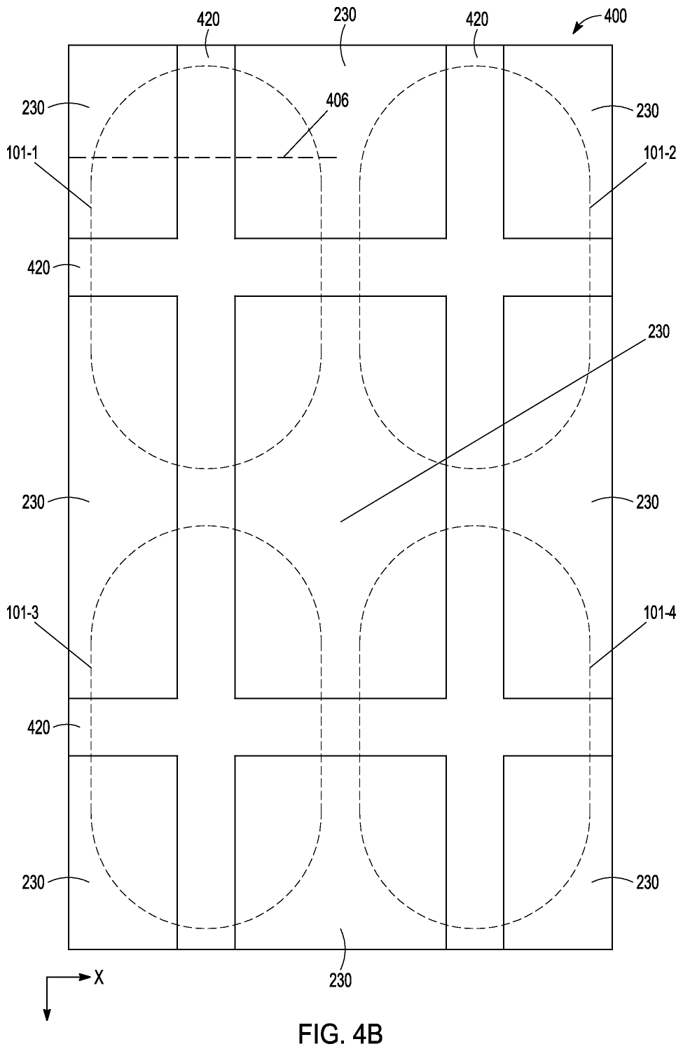

FIG. 4A shows a cross-sectional view of a structure 400 after processing structure 300 of FIGS. 3A-3B and is a cross-sectional view along dashed line 406 of FIG. 4B. The results shown in FIG. 4A are for an embodiment of further processing structure 300 of a number of embodiments for further processing structure 300. A low-k material 420 has been deposited in operning 309 inside container structure 101-1 of structure 300 to a top level of the tops of isolation regions 135. The deposited low-k material 420 electrically isolates material for bottom electrode 305-1-1 from material for bottom electrode 305-1-2. This low-k material formation provides a substitution for the high-k dielectric deposited in previous conventional processes. The low-k material formation has also been formed in each of container structures 101-2, 101-3, and101-4.

FIG. 4B is a top view of structure 400 of FIG. 4A from a level of dashed line 406 of FIG. 4A. This top view shows container structures 101-1 and 101-2 of FIG. 4A along with container structures 101-3 and 101-4. FIG. 4B further demonstrates the result of forming low-k material 420 in openings among photoresist 230.

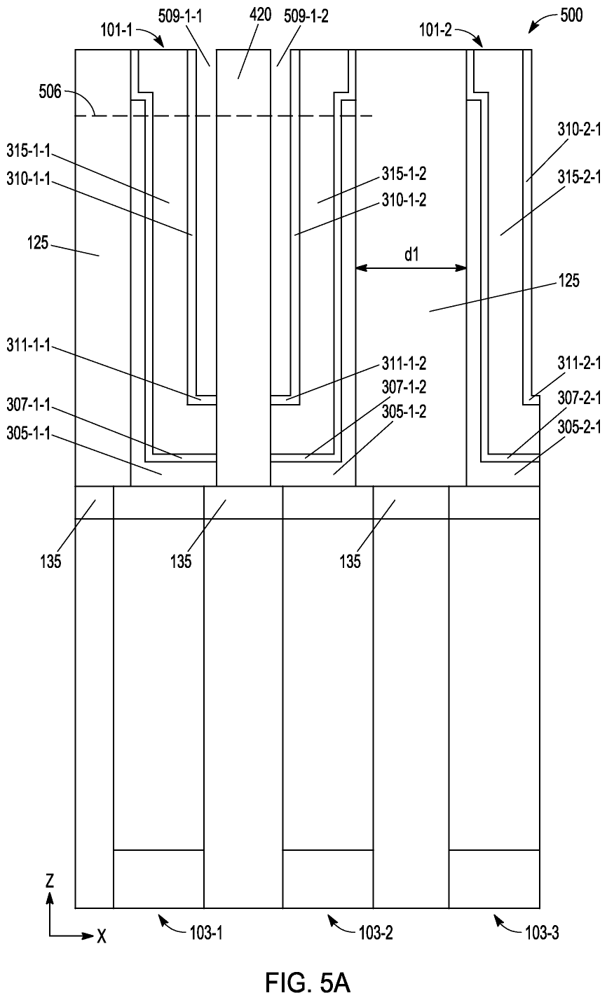

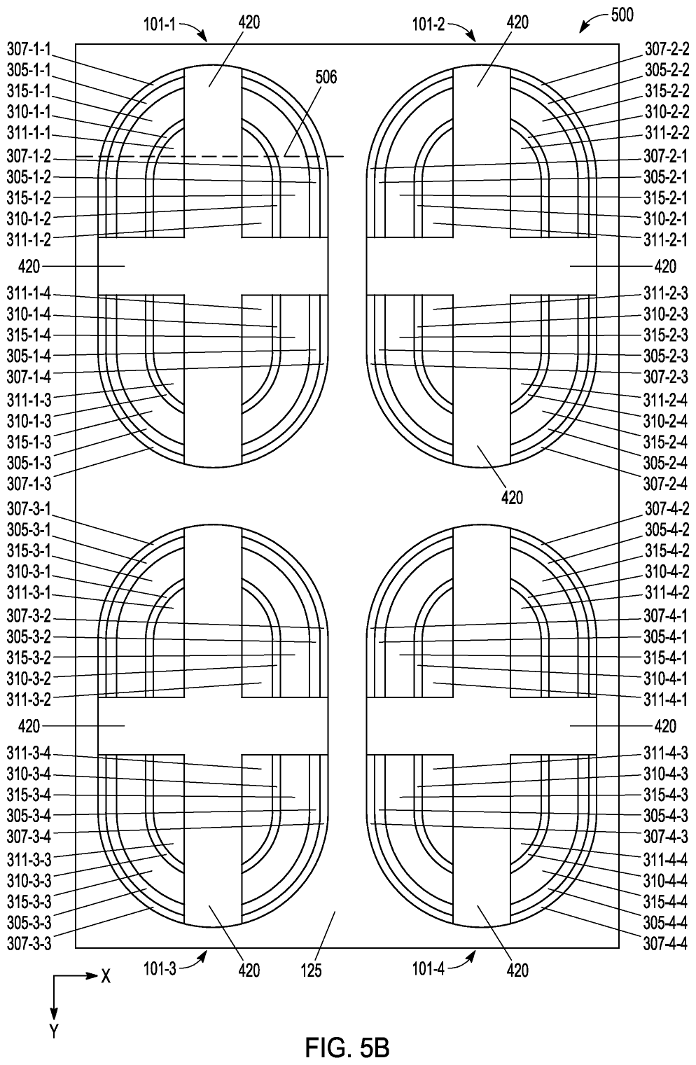

FIG. 5A shows a cross-sectional view of a structure 500 after processing structure 400 of FIGS. 4A-4B and is a cross-sectional view along dashed line 506 of FIG. 5B. Low-k material 420 is etched back and has been subjected to a chemical mechanical polishing (CMP) process to a level 518 of a container surface of container structure 101-1. Photoresist 230 has been stripped. The photoresist strip forms openings 509-1-1 and 509-1-2, exposing surfaces of material for top electrodes 310-1-1 and 310-1-2 in container structure 101-1. The openings 509-1-1 and 509-1-2 have been made for further processing electrical contact to a plate for the ferroelectric of the memory cell being formed. The material of container structures 101-2, 101-3, and 101-4 have been processed in the same manner as the material of container structure 101-1.

FIG. 5B is a top view of structure 500 of FIG. 5A from the level of dashed line 506 of FIG. 5A. This top view shows container structures 101-1 and 101-2 of FIG. 5A along with container structures 101-3 and 101-4, where these container structures are separated by dielectric material 125. FIG. 5B shows container structure 101-1 separated into four regions for a ferroelectric capacitor in each region of container structure 101-1 by the formation of low-k material 420. One region of container structure 101-1 includes material for leaker 307-1-1, material for bottom electrode 305-1-1, ferroelectric material 315-1-1, material for top electrode 310-1-1, and horizontal base 311-1-1 for top electrode 310-1-1 with respect to low-k material 420 in container structure 101-1. A second region of container structure 101-1 includes material for leaker 307-1-2, material for bottom electrode 305-1-2, ferroelectric material 315-1-2, material for top electrode 310-1-2, and horizontal base 311-1-2 for top electrode 310-1-2 with respect to low-k material 420 in container structure 101-1. A third region of container structure 101-1 includes material for leaker 307-1-3, material for bottom electrode 305-1-3, ferroelectric material 315-1-3, material for top electrode 310-1-3, and horizontal base 311-1-3 for top electrode 310-1-3 with respect to low-k material 420 in container structure 101-1. A fourth region of container structure 101-1 includes material for leaker 307-1-4, material for bottom electrode 305-1-4, ferroelectric material 315-1-4, material for top electrode 310-1-4, and horizontal base 311-1-4 for top electrode 310-1-4 with respect to low-k material 420 in container structure 101-1.

FIG. 5B shows container structure 101-2 separated into four regions for a ferroelectric capacitor in each region of container structure 101-2 by the formation of low-k material 420. One region of container structure 101-2 includes material for leaker 307-2-1, material for bottom electrode 305-2-1, ferroelectric material 315-2-1, material for top electrode 310-2-1, and horizontal base 311-2-1 for top electrode 310-2-1 with respect to low-k material 420 in container structure 101-2. A second region of container structure 101-2 includes material for leaker 307-2-2, material for bottom electrode 305-2-2, ferroelectric material 315-2-2, material for top electrode 310-2-2, and horizontal base 311-2-2 for top electrode 310-2-2 with respect to low-k material 420 in container structure 101-2. A third region of container structure 101-2 includes material for leaker 307-2-3, material for bottom electrode 305-2-3, ferroelectric material 315-2-3, material for top electrode 310-2-3, and horizontal base 311-2-3 for top electrode 310-2-3 with respect to low-k material 420 in container structure 101-2. A fourth region of container structure 101-2 includes material for leaker 307-2-4, material for bottom electrode 305-2-4, ferroelectric material 315-2-4, material for top electrode 310-2-4, and horizontal base 311-2-4 for top electrode 310-2-4 with respect to low-k material 420 in container structure 101-2.

FIG. 5B shows container structure 101-3 separated into four regions for a ferroelectric capacitor in each region of container structure 101-3 by the formation of low-k material 420. One region of container structure 101-3 includes material for leaker 307-3-1, material for bottom electrode 305-3-1, ferroelectric material 315-3-1, material for top electrode 310-3-1, and horizontal base 311-3-1 for top electrode 310-3-1 with respect to low-k material 420 in container structure 101-3. A second region of container structure 101-3 includes material for leaker 307-3-2, material for bottom electrode 305-3-2, ferroelectric material 315-3-2, material for top electrode 310-3-2, and horizontal base 311-3-2 for top electrode 310-3-2 with respect to low-k material 420 in container structure 101-3. A third region of container structure 101-3 includes material for leaker 307-3-3, material for bottom electrode 305-3-3, ferroelectric material 315-3-3, material for top electrode 310-3-3, and horizontal base 311-3-3 for top electrode 310-3-3 with respect to low-k material 420 in container structure 101-3. A fourth region of container structure 101-3 includes material for leaker 307-3-4, material for bottom electrode 305-3-4, ferroelectric material 315-3-4, material for top electrode 310-3-4, and horizontal base 311-3-4 for top electrode 310-3-4 with respect to low-k material 420 in container structure 101-3.

FIG. 5B shows container structure 101-4 separated into four regions for a ferroelectric capacitor in each region of container structure 101-4 by the formation of low-k material 420. One region of container structure 101-4 includes material for leaker 307-4-1, material for bottom electrode 305-4-1, ferroelectric material 315-4-1, material for top electrode 310-4-1, and horizontal base 311-4-1 for top electrode 310-4-1 with respect to low-k material 420 in container structure 101-4. A second region of container structure 101-4 includes material for leaker 307-4-2, material for bottom electrode 305-4-2, ferroelectric material 315-4-2, material for top electrode 310-4-2, and horizontal base 311-4-2 for top electrode 310-4-2 with respect to low-k material 420 in container structure 101-4. A third region of container structure 101-4 includes material for leaker 307-4-3, material for bottom electrode 305-4-3, ferroelectric material 315-4-3, material for top electrode 310-4-3, and horizontal base 311-4-3 for top electrode 310-4-3 with respect to low-k material 420 in container structure 101-4. A fourth region of container structure 101-4 includes material for leaker 307-4-4, material for bottom electrode 305-4-4, ferroelectric material 315-4-4, material for top electrode 310-4-4, and horizontal base 311-4-4 for top electrode 310-4-4 with respect to low-k material 420 in container structure 101-4.

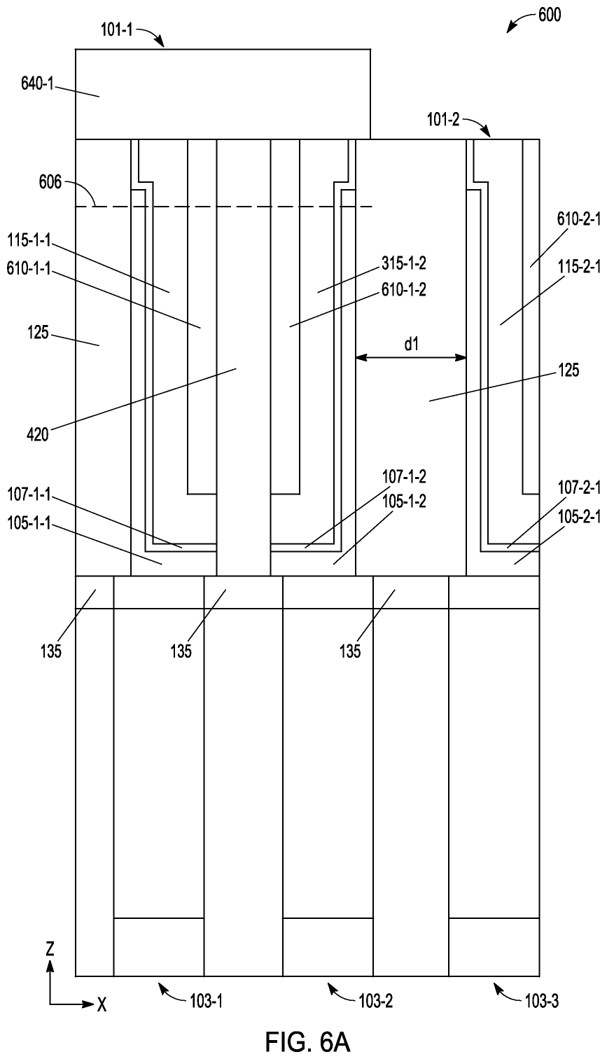

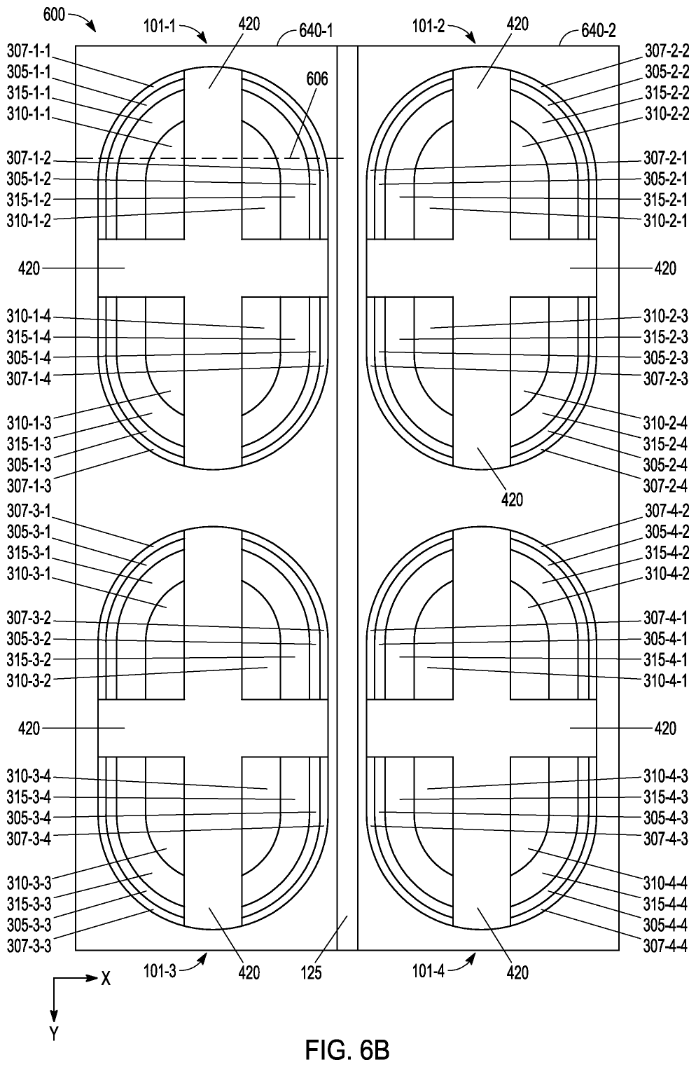

FIG. 6A shows a cross-sectional view of a structure 600 after processing structure 500 of FIGS. 5A-5B and is a cross-sectional view along dashed line 606 of FIG. 6B. Openings 509-1-1 and 509-1-2 have been filled with the material for top electrodes 310-1-1 and 310-1-2, forming top electrodes 610-1-1 and 610-1-2, respectively. A plate 640-1 has been formed on the tops of dielectric material 125, material for leaker 107-1-1, ferroelectric material 115-1-1, and top electrode 610-1-1 and on the tops of material for leaker 107-1-2, ferroelectric material 115-1-2, and top electrode 610-1-2 in container structure 101-1. Plate 640-1 is a conductive structure. Plate 640-1 has also been formed on low-k material 420. Container structures 101-2, 101-3, and 101-4 have been formed in the same manner as container structure 101-1.

FIG. 6B is a top view of structure 600 of FIG. 6A from the level of dashed line 606 of FIG. 6A. This top view shows container structures 101-1 and 101-2 of FIG. 6A along with container structures 101-3 and 101-4, where these container structures are separated by dielectric material 125. FIG. 6B shows container structure 101-1 separated into four regions for a ferroelectric capacitor in each region of container structure 101-1 by the formation of low-k material 420 to form a memory cell associated with each of the four regions. A plate 640-1 has been formed on the tops of dielectric material, material for a leaker, dielectric material, and a top electrode in each region of container structure 101-1 and each region of container structure 101-3. A plate 640-2 has been formed on the tops of dielectric material, material for a leaker, dielectric material, and a top electrode in each region of container structure 101-2 and each region of container structure 101-4. Low-k material 420 effectively guarantees better bottom-electrode to bottom-electrode disturb performances of adjacent memory cells. The above process can be performed without use of additional masks with respect to conventional processes. The process flow of FIGS. 1A-6B may be affected by strict alignment constraints and high resistance due to small surface of the top electrodes formed in the process flow demonstrated by FIGS. 1A-6B.

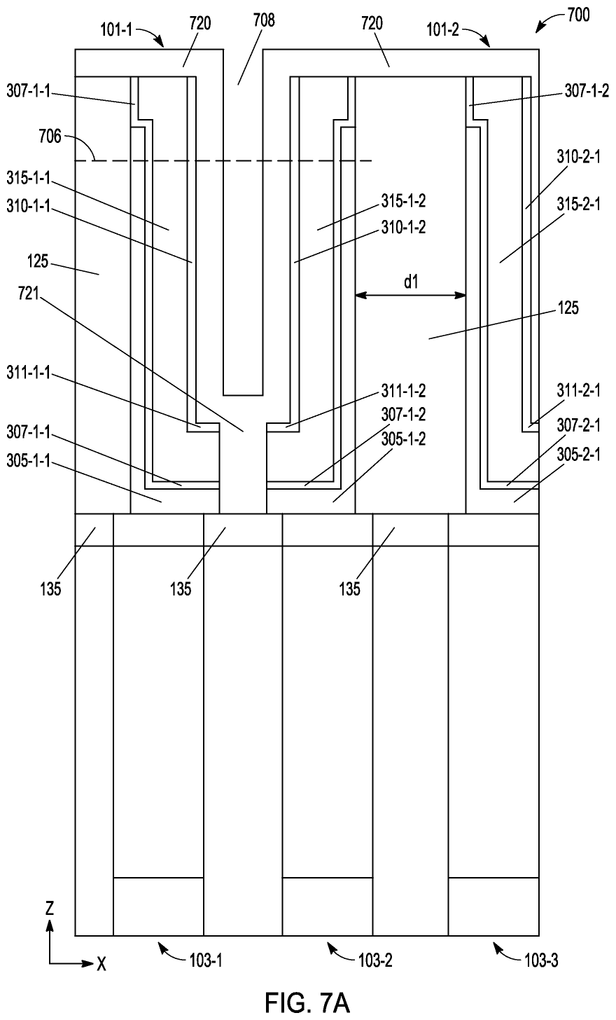

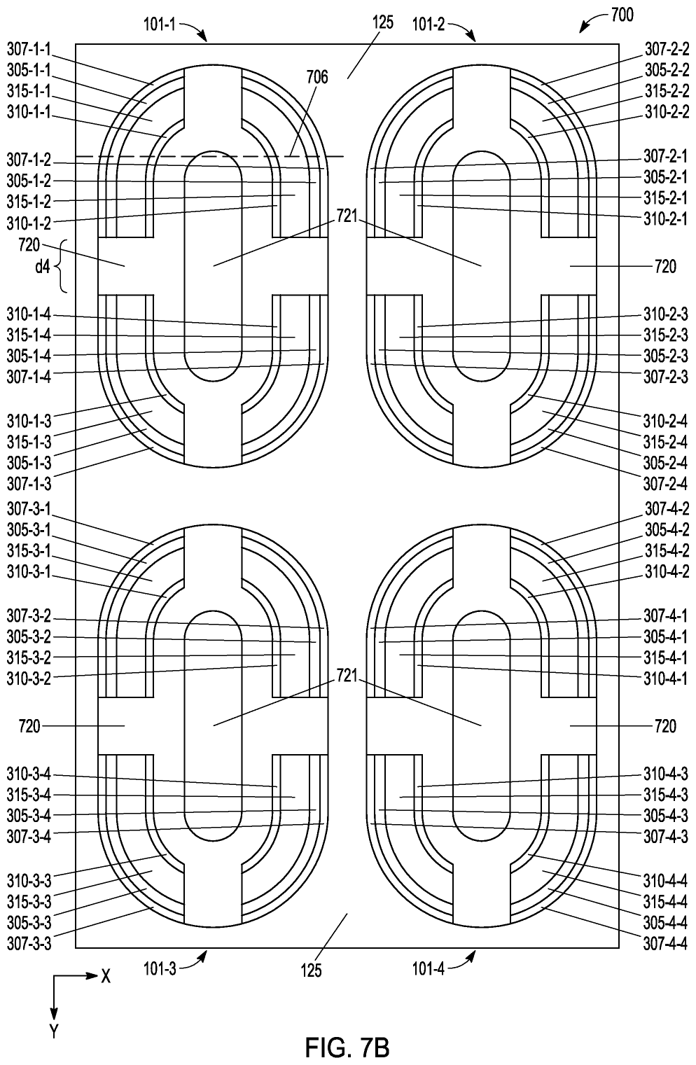

FIG. 7A shows a cross-sectional view of a structure 700 after processing structure 300 of FIGS. 3A-3B and is a cross-sectional view along dashed line 706 of FIG. 7B. The results shown in FIG. 7A are for another embodiment of further processing structure 300 of a number of embodiments for further processing structure 300. A conformal deposition of low-k material 720 has been performed to a same thickness throughout the array of memory cells with a thickness such that the low-k material forms a low-k material 721 between the material for bottom electrode 305-1-1 and the material for bottom electrode 305-1-2. Low-k material 721 has also been formed between the material for leaker 307-1-1 and the material for leaker 307-1-2, between ferroelectric material 315-1-1 and ferroelectric material 315-1-2, and between horizontal base 311-1-1 for top electrode 310-1-1 and horizontal base 311-1-2 for top electrode 310-1-2. Low-k material 721 has also been formed above horizontal base 311-1-1 and horizontal base 311-1-2, but leaves a portion of opening 309 open, forming opening 709. A conformal deposition thicker than, but not limited to, about five nanometers allows the opening (hole) 309 of structure 300 to be filled between the material for bottom electrode 305-1-1 and the material for bottom electrode 305-1-2. The depth of opening 309 forming opening 709 can be trimmed, changing the thickness of the material of top electrode 310-1-1 and top electrode 310-1-2.

FIG. 7B is a top view of structure 700 of FIG. 7A from a level of dashed line 706 of FIG. 7A. This top view shows container structures 101-1 and 101-2 of FIG. 7A along with container structures 101-3 and 101-4. FIG. 7B further demonstrates the result of forming low-k material 721 at the bottom of opening 709 to a level significantly less than low-k material 720 along and above the material for top electrode 310-1-1 and top electrode 310-1-2.

FIG. 7B is a top view of structure 700 of FIG. 7A from the level 706 of FIG. 7A. This top view shows container structures 101-1 and 101-2 of FIG. 7A along with container structures 101-3 and 101-4, where these container structures are separated by dielectric material 125. FIG. 7B shows container structure 101-1 separated into four regions for a ferroelectric capacitor in each region of container structure 101-1 by the formation of low-k material 720. One region of container structure 101-1 includes material for leaker 307-1-1, material for bottom electrode 305-1-1, ferroelectric material 315-1-1, and material for top electrode 310-1-1, shown with respect to low-k material 720 in container structure 101-1. A second region of container structure 101-1 includes material for leaker 307-1-2, material for bottom electrode 305-1-2, ferroelectric material 315-1-2, and material for top electrode 310-1-2, shown with respect to low-k material 720 in container structure 101-1. A third region of container structure 101-1 includes material for leaker 307-1-3, material for bottom electrode 305-1-3, ferroelectric material 315-1-3, and material for top electrode 310-1-3, shown with respect to low-k material 720 in container structure 101-1. A fourth region of container structure 101-1 includes material for leaker 307-1-4, material for bottom electrode 305-1-4, ferroelectric material 315-1-4, and material for top electrode 310-1-4, shown with respect to low-k material 720 in container structure 101-1.

FIG. 7B shows container structure 101-2 separated into four regions for a ferroelectric capacitor in each region of container structure 101-2 by the formation of low-k material 720. One region of container structure 101-2 includes material for leaker 307-2-1, material for bottom electrode 305-2-1, ferroelectric material 315-2-1, and material for top electrode 310-2-1, shown with respect to low-k material 720 in container structure 101-2. A second region of container structure 101-2 includes material for leaker 307-2-2, material for bottom electrode 305-2-2, ferroelectric material 315-2-2, and material for top electrode 310-2-2, shown with respect to low-k material 720 in container structure 101-2. A third region of container structure 101-2 includes material for leaker 307-2-3, material for bottom electrode 305-2-3, ferroelectric material 315-2-3, and material for top electrode 310-2-3, shown with respect to low-k material 720 in container structure 101-2. A fourth region of container structure 101-2 includes material for leaker 307-2-4, material for bottom electrode 305-2-4, ferroelectric material 315-2-4, and material for top electrode 310-2-4, shown with respect to low-k material 720 in container structure 101-2.

FIG. 7B shows container structure 101-3 separated into four regions for a ferroelectric capacitor in each region of container structure 101-3 by the formation of low-k material 720. One region of container structure 101-3 includes material for leaker 307-3-1, material for bottom electrode 305-3-1, ferroelectric material 315-3-1, and material for top electrode 310-3-1, shown with respect to low-k material 720 in container structure 101-3. A second region of container structure 101-3 includes material for leaker 307-3-2, material for bottom electrode 305-3-2, ferroelectric material 315-3-2, and material for top electrode 310-3-2, shown with respect to low-k material 720 in container structure 101-3. A third region of container structure 101-3 includes material for leaker 307-3-3, material for bottom electrode 305-3-3, ferroelectric material 315-3-3, and material for top electrode 310-3-3, shown with respect to low-k material 720 in container structure 101-3. A fourth region of container structure 101-3 includes material for leaker 307-3-4, material for bottom electrode 305-3-4, ferroelectric material 315-3-4, and material for top electrode 310-3-4, shown with respect to low-k material 720 in container structure 101-3.

FIG. 7B shows container structure 101-4 separated into four regions for a ferroelectric capacitor in each region of container structure 101-4 by the formation of low-k material 720. One region of container structure 101-4 includes material for leaker 307-4-1, material for bottom electrode 305-4-1, ferroelectric material 315-4-1, and material for top electrode 310-4-1, shown with respect to low-k material 720 in container structure 101-4. A second region of container structure 101-4 includes material for leaker 307-4-2, material for bottom electrode 305-4-2, ferroelectric material 315-4-2, and material for top electrode 310-4-2, shown with respect to low-k material 720 in container structure 101-4. A third region of container structure 101-4 includes material for leaker 307-4-3, material for bottom electrode 305-4-3, ferroelectric material 315-4-3, and material for top electrode 310-4-3, shown with respect to low-k material 720 in container structure 101-4. A fourth region of container structure 101-4 includes material for leaker 307-4-4, material for bottom electrode 305-4-4, ferroelectric material 315-4-4, and material for top electrode 310-4-4, shown with respect to low-k material 720 in container structure 101-4.

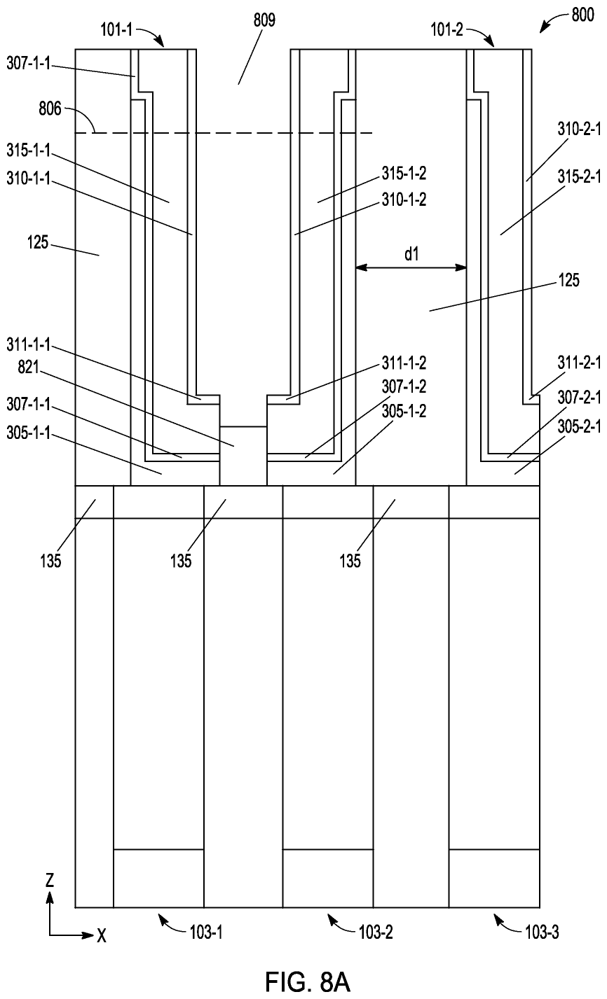

FIG. 8A shows a cross-sectional view of a structure 800 after processing structure 700 of FIGS. 7A-7B and is a cross-sectional view along dashed line 806 of FIG. 8B. Low-k material 720 and a portion of low-k material 721 has been removed, exposing the surface of the material for top electrodes 310-1-1 and 310-1-2, and forming an opening 809 larger than opening 709 of structure 700. Removal of low-k material 720 has been performed to expose top surfaces of dielectric material 125, the material for leakers 307-1-1 and 307-1-2, dielectric materials 315-1-1 and 315-1-2, and the material for top electrodes 310-1-1 and 310-1-2. The removal process has been performed allowing a uniform low-k recession of low-k material 721, leaving the low-k material 821 only between the material of leaker 307-1-1 and the material of leaker 307-1-2, between ferroelectric material 315-1-1 and ferroelectric material 315-1-2, and between the material for bottom electrode 305-1-1 and the material for bottom electrode 305-1-2. This process effectively substitutes low-k material for deposited high-k material previously used in conventional structures and provides desired electrical isolation. Container structures 101-2, 101-3, and 101-4 have been processed in the same manner as container structure 101-1.

If the uniform recession of low-k material 720 and a portion of low-k material 721 does not completely remove the low-k material 720 on the top of the material formed in container structure 101-1, a CMP can be performed to allow exposure of the top surfaces of dielectric material 125, the material for leakers 307-1-1 and 307-1-2, ferroelectric materials 315-1-1 and 315-1-2, and the material for top electrodes 310-1-1 and 310-1-2, removing the residual low-k material on the materials of container structure 101-1. Exposure of the material for leakers 307-1-1 and 307-1-2 has been performed for subsequent electrical contact to a plate electrode.

FIG. 8B is a top view of structure 800 of FIG. 8A from a level of dashed line 806 of FIG. 8A. This top view shows container structures 101-1 and 101-2 of FIG. 8A along with container structures 101-3 and 101-4. FIG. 8B further demonstrates the result of forming low-k material 821 at the bottom of opening 809 with low-k material 720 remaining between the four regions of each of container structures 101-1, 101-2, 101-3, and 101-4. At the level of dashed line 806, horizontal base 311-1-1 for top electrode 310-1-1, horizontal base 311-1-2 for a top electrode 310-1-2, horizontal base 311-1-3 for top electrode 310-1-3 and a horizontal base 311-1-4 for a top electrode 310-1-4 in container structure 101-1 are also shown with respect to low-k material 720. At the level of dashed line 806, horizontal base 311-2-1 for top electrode 310-2-1, horizontal base 311-2-2 for a top electrode 310-2-2, horizontal base 311-2-3 for top electrode 310-2-3 and a horizontal base 311-2-4 for a top electrode 310-2-4 in container structure 101-2 are also shown with respect to low-k material 720. At level of dashed line 806, horizontal base 311-3-1 for top electrode 310-3-1, horizontal base 311-3-2 for a top electrode 310-3-2, horizontal base 311-3-3 for top electrode 310-3-3 and a horizontal base 311-3-4 for a top electrode 310-3-4 in container structure 101-3 are also shown with respect to low-k material 720. At level of dashed line 806, horizontal base 311-4-1 for top electrode 310-4-1, horizontal base 311-4-2 for a top electrode 310-4-2, horizontal base 311-4-3 for top electrode 310-4-3 and a horizontal base 311-4-4 for a top electrode 310-4-4 in container structure 101-4 are also shown with respect to low-k material 720.

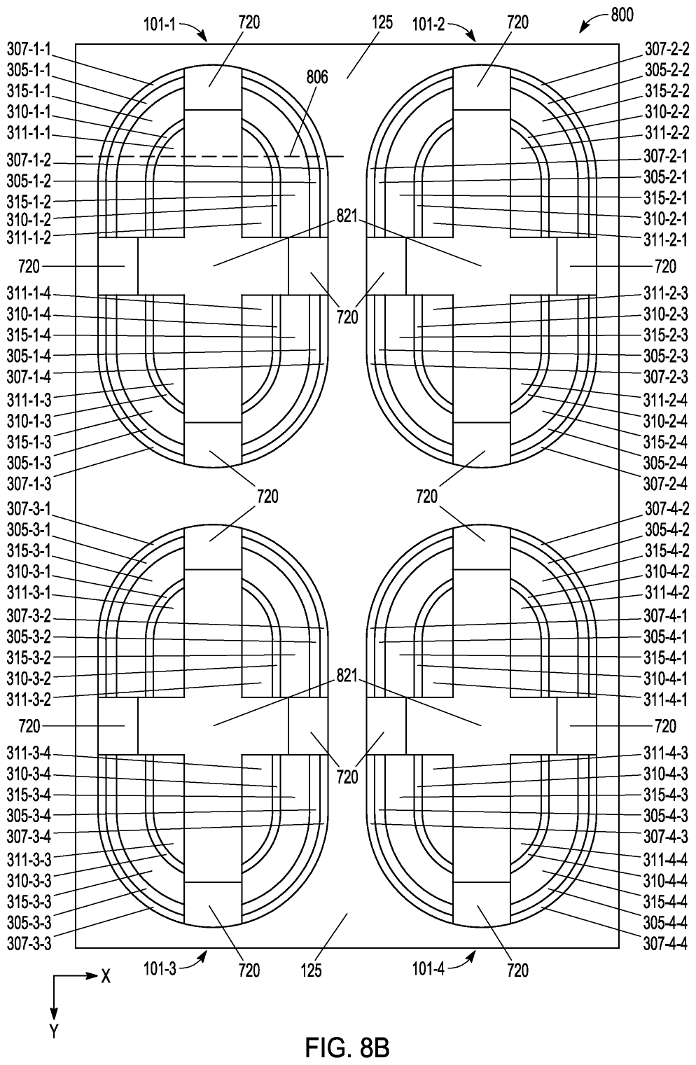

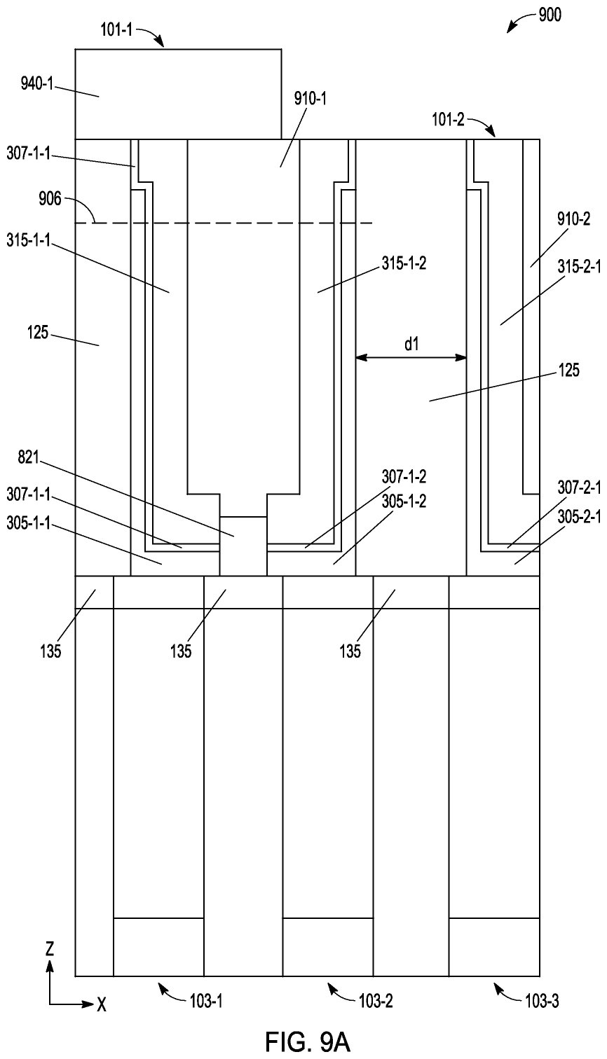

FIG. 9A shows a cross-sectional view of a structure 900 after processing structure 800 of FIGS. 8A-8B and is a cross-sectional view along dashed line 906 of FIG. 9B. Opening 809 of structure 800 has been filled with material for a top electrode 910-1, effectively combining the material for top electrodes 310-1-1 and 310-1-2. Top electrode 910-1 forms a single top electrode for top electrodes of ferroelectric capacitors in container structure 101-1. A plate 940-1 has been formed on the tops of dielectric material 125, material for leaker 107-1-1, ferroelectric material 115-1-1, and top electrode 910-1 in container structure 101-1. Plate 940-1 is a conductive structure. Container structures 101-2, 101-3, and 101-4 have been formed in the same manner as container structure 101-1.

FIG. 9B is a top view of structure 900 of FIG. 9A from the level of dashed line 906 of FIG. 9A. This top view shows container structures 101-1 and 101-2 of FIG. 9A along with container structures 101-3 and 101-4, where these container structures are separated by dielectric material 125. FIG. 9B shows container structure 101-1 separated into four regions for a ferroelectric capacitor in each region of container structure 101-1 by the formation of low-k material 720 to form a memory cell associated with each of the four regions. A plate 940-1 has been formed partially on the tops of the components of container structure 101-1 and container structure 101-3 such that 940-1 is electrically coupled to a single top electrode 910-1 of container structure 101-1 and to single top electrode 910-3 of container structure 101-3. A plate 940-2 has been formed partially on the tops of the components of container structure 101-2 and container structure 101-4 such that 940-2 is electrically coupled to a single top electrode 910-2 of container structure 101-2 and to single top electrode 910-4 of container structure 101-4.

Structure 900 of FIGS. 9A-9B, from the process flow of FIGS. 1A-3B and 7A-9B, provides an approach that addresses the small area of the top electrodes of the ferroelectric capacitors of structure 600 of FIGS. 6A-6B, from the process flow of FIGS. 1A-6B, since the low-k material is formed only between the bottom electrodes, ferroelectric material, and leakers at a level below the bottom of the top electrode for adjacent memory cells and does not remarkably affect the contact of top electrodes. The low-k material inclusion in structure 900 does not affect the effective cell area, since it simply replaces the unused portion of a dielectric of conventional architectures. Process flow of FIGS. 1A-6B uses a thinner plate cut to guarantee electrical contact with top electrodes of the ferroelectric capacitors, while the process flow of FIGS. 1A-3B and 7A-9B facilitate enhanced plate cut process tolerances. In addition, each of these two process approaches can be performed without additional lithographic masks compared to conventional approaches. Each of structure 900 of FIGS. 9A-9B and structure 600 of FIGS. 6A-6B provides a mechanism that effectively decreases disturb risk for adjacent memory cells of a memory die.

In the process flows discussed above or variations thereof and in completed memory cells having ferroelectric capacitors as storage structures, various materials can be selected to be used in the components of the various structures. Conductive materials for bottom electrodes and top electrodes of ferroelectric capacitors can include, but are not limited to, titanium, titanium nitride, tungsten nitride, or combinations of these materials. Materials for the ferroelectric between the bottom electrodes and top electrodes of ferroelectric capacitors can include, but are not limited to, hafnium oxide, zirconium oxide, or combinations of hafnium oxide and zirconium oxide. Materials for the low-k dielectrics (dielectrics having a dielectric constant less than the dielectric constant of silicon dioxide) that separate bottom electrodes of adjacent memory cells can include, but are not limited to, silicon oxide, silicon oxycarbide, fluorine doped silicon glass, porous silicon dioxide, or combinations of these dielectrics.

Various deposition techniques for components of structures in the process flows discussed above or similar structures and process flows can be used that are typical for the material being formed, the dimensions of the material being formed, and the architecture in which the material is being formed. Processes for forming the various materials can include, but are not limited to, chemical vapor deposition (CVD), atomic layer deposition (ALD), and physical vapor deposition (PVD). PVD can include, but is not limited to, sputtering, ion beam deposition, electron beam evaporation, pulsed laser deposition, and vacuum arc methods, among others. CVD can include, but is not limited to, plasma chemical vapor deposition, and laser chemical vapor deposition, among others. Selective etching and conventional masking techniques can be used to remove selected regions in the processing. Etching procedures can include, but are not limited to, wet etching, dry etching, and atomic layer etching deposition, among others.

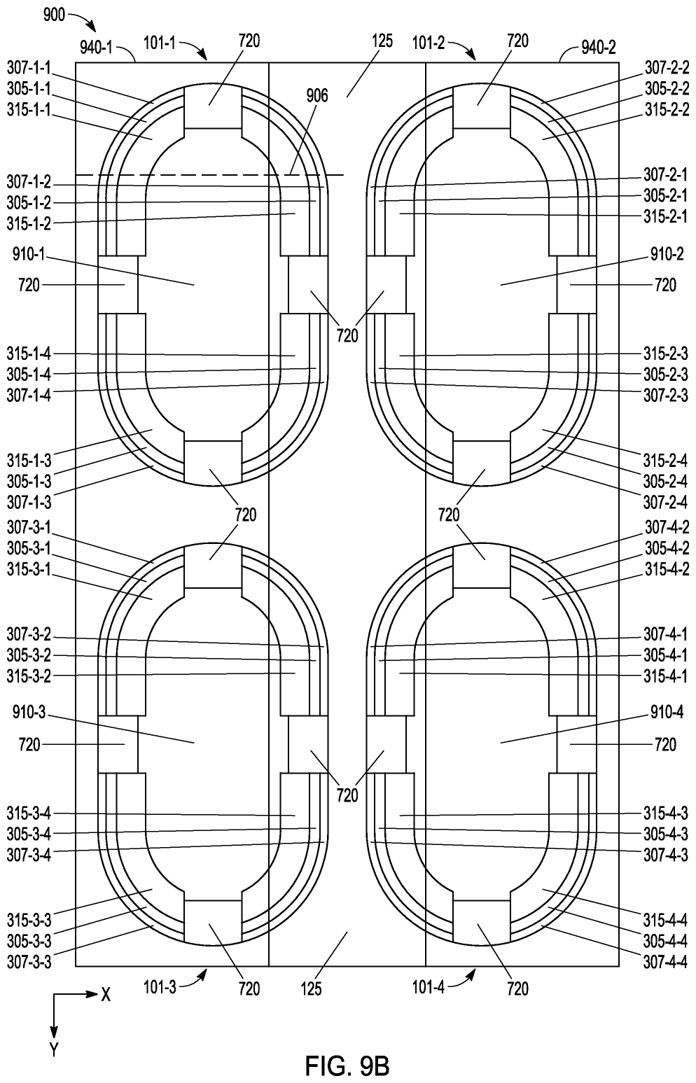

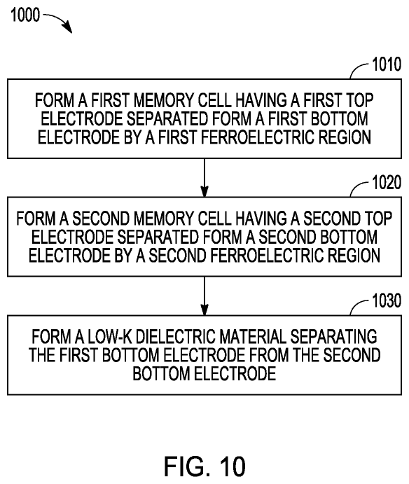

FIG. 10 is a flow diagram of features of an embodiment of an example method 1000 of forming components of a memory device. At 1010, a first memory cell is formed having a first top electrode separated from a first bottom electrode by a first ferroelectric region. At 1020, a second memory cell is formed having a second top electrode separated from a second bottom electrode by a second ferroelectric region. At 1030, a low-k dielectric material is formed separating the first bottom electrode from the second bottom electrode. The various procedures associated with 1010, 1020, and 1030 can be conducted in various manners including forming these features in a common procedure. The various procedures associated with 1010, 1020, and 1030 can be implemented to form different embodiments of ferroelectric capacitors coupled to access transistors to form memory cells of the memory device.

Variations of method 1000 or methods similar to method 1000 can include a number of different embodiments that may be combined depending on the application of such methods and/or the architecture of systems including a memory device in which such methods are implemented. Such methods can include forming a continuous conductive material for the first bottom electrode and the second bottom electrode on a surface above a region for access transistors for the first memory cell and the second memory cell. Ferroelectric material, for the first ferroelectric region and the second ferroelectric region, can be formed on the continuous conductive material. A second conductive material, for the first top electrode and the second top electrode, can be formed on the ferroelectric material. Portions of the ferroelectric material, portions of the continuous conductive material, and portions of the second conductive material can be removed, forming an opening from above a level for a top surface of the ferroelectric material to the surface above the region for access transistors. The low-k dielectric material can be formed using the opening to separate the first bottom electrode from the second bottom electrode.

Variations can include removing portions of the ferroelectric material, portions of the continuous conductive material, and portions of the second conductive material by etching to separate the first bottom electrode and the second bottom electrode and bottom electrodes of other adjacent cells being formed in a first container structure containing the first memory cell and the second memory cell. Such etching can be selective to substantially maintain an isolation dielectric between the first container structure and an adjacent container structure for forming memory cells.

Variations can include forming the low-k dielectric material using the opening by filling the opening with the low-k dielectric material, including forming the low-k dielectric material on a photoresist formed on the second conductive material, where the photoresist can be formed before removing the portions of the second conductive material. The photoresist can be removed while maintaining the low-k dielectric material filling the opening, forming a first open region between the low-k dielectric material and the second conductive material and a second open region between the low-k dielectric material and the second conductive material. The first top electrode can be formed in the first open region and the second top electrode can be formed in the second open region such that the low-k dielectric material separates the first top electrode from the second top electrode, the first ferroelectric region from the second ferroelectric region, and the first bottom electrode from the second bottom electrode.

Variations can include forming the low-k dielectric material using the opening by conformally forming the low-k dielectric material in the opening including forming the low-k material on the second conductive material. The low-k dielectric material can be removed leaving a portion of the low-k dielectric material such that the low-k dielectric material is recessed below a bottom of the second conductive material and is positioned between the first bottom electrode and the second bottom electrode. A third conductive material can be formed on the recessed low-k dielectric material and on the second conductive material, extending from the recessed low-k dielectric material to a top level of the ferroelectric material for the first ferroelectric region and the second ferroelectric region. The third conductive material can be arranged as the first top electrode and the second top electrode.

In various embodiments, a first memory device can comprise a first memory cell having a first top electrode separated from a first bottom electrode by a first ferroelectric region; a second memory cell having a second top electrode separated from a second bottom electrode by a second ferroelectric region; and a low-k dielectric material separating the first bottom electrode from the second bottom electrode.

Variations of such a first memory device and its features, as taught herein, can include a number of different embodiments and features that can be combined depending on the application of such memory devices, the format of such memory devices, and/or the architecture in which such memory devices are implemented. Variations of such first memory devices can include electrode material of the first top electrode, the first bottom electrode, the second top electrode, or the second bottom electrode having, but not limited to, one or more of titanium, titanium nitride, or tungsten nitride. Such variations can include ferroelectric material of the first ferroelectric region or the second ferroelectric region including, but not limited to, hafnium oxide, zirconium oxide, or a combination of hafnium oxide and zirconium oxide. Such variations can include the low-k dielectric material including, but not limited to, one or more of silicon oxide, silicon oxycarbide, fluorine doped silicon glass, or porous silicon oxide, where the silicon oxide has dielectric constant of 3.5 or less.

Variations of such first memory devices can include a plate coupled to the first top electrode and to the second top electrode. The low-k dielectric material can be structured to separate the first top electrode from the second top electrode; contact the first bottom electrode and the second bottom electrode at a vertical level below the first top electrode and the second top electrode; and extend from the vertical level at which the low-k dielectric material contacts the first bottom electrode and the second bottom electrode to the plate. Variations can include the first top electrode and the second top electrode being configured as a single continuous electrode located on and extending vertically from the low-k dielectric material to contact the plate. Variations can include the first memory device having a leaker on and contacting the first bottom electrode and located under and coupled to the plate.

In various embodiments, a second memory device can comprise access lines, digit lines, and an array of memory cells. Each memory cell can have an access transistor coupled to one of the access lines and can have a storage structure coupled to one of the digit lines via the access transistor. The storage structure can include a top electrode separated from a bottom electrode by a ferroelectric region, where the bottom electrode is separated from a bottom electrode of an adjacent memory cell by a low-k dielectric material.

Variations of such a second memory device and its features, as taught herein, can include a number of different embodiments and features that can be combined depending on the application of such memory devices, the format of such memory devices, and/or the architecture in which such memory devices are implemented. Variations of such second memory devices can include each memory cell being positioned within a container structure with three adjacent memory cells. The array can have multiple container structures separated by isolation dielectrics, where each container structure contains four memory cells adjacent to each other with bottom electrodes of storage structures of the adjacent memory cells separated by the low-k dielectric material. The low-k dielectric material can separate the ferroelectric region from a ferroelectric region of the adjacent memory cell and can separate the top electrode from a top electrode of the adjacent memory cell. The low-k material can extend from a bottom level of the bottom electrode to a plate positioned on a top surface of the top electrode and a top surface of the top electrode of the adjacent memory cell.

Variations of such second memory devices can include the low-k dielectric material separating the ferroelectric region from a ferroelectric region of the adjacent memory cell, where the top electrode can be positioned on the low-k dielectric material and can be the top electrode of the adjacent memory cell. Variations can include the low-k dielectric material separating the bottom electrode from the bottom electrode of the adjacent memory cell by a distance equal to or less than about ten nanometers.

Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., internet-of-things (IoT) devices, etc.), have varying storage needs depending on, among other things, the type of electronic device, use environment, performance expectations, etc. Electronic devices can be broken down into several main components: a processor (e.g., a central processing unit (CPU) or other main processor); memory (e.g., one or more volatile or non-volatile RAM memory device, such as FeRAM, DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor” means a computational circuit including a group of processors or multi-core devices. Such electronic devices can be implemented with architectures for FeRAMs including ferroelectric capacitors as taught herein or other memory devices using non-ferroelectric capacitors having the architecture for ferroelectric storage capacitors as taught herein.

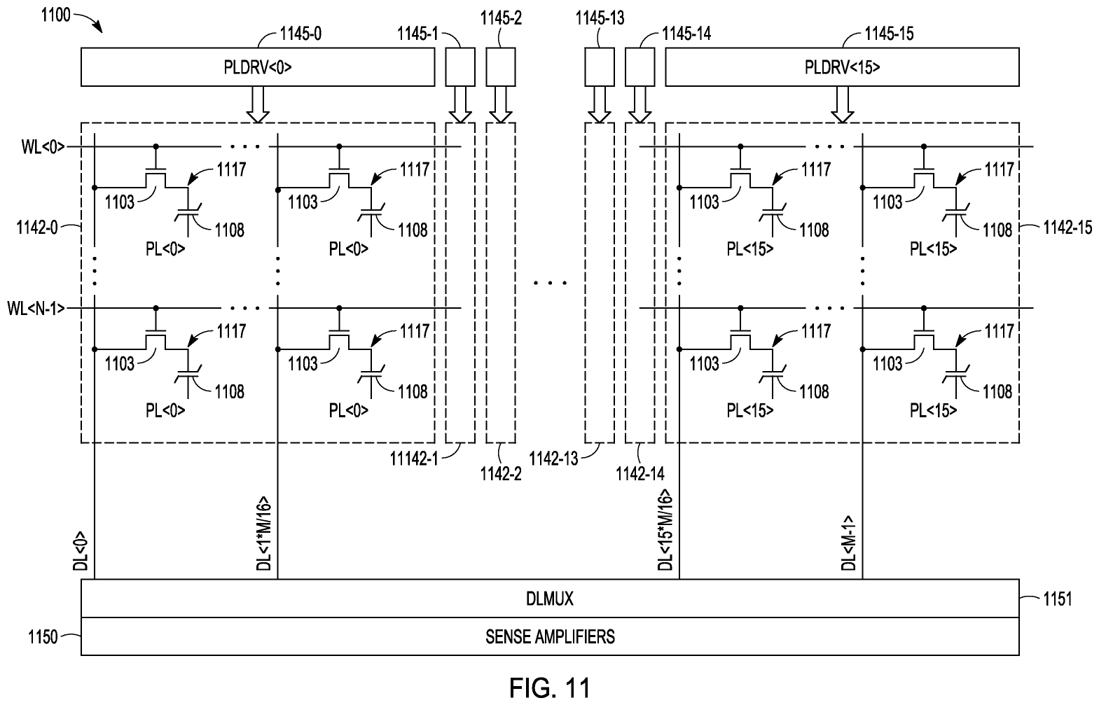

FIG. 11 is a schematic of an embodiment of an example memory device 1100 that can include an architecture having a memory array arranged in subarrays 1142-0, 1142-1, 1142-2 . . . 1142-13, 1142-14, and 1142-15, which can be structured in conjunction with an arrangement of memory cells having ferroelectric capacitor similar to FIGS. 6A-6B, FIGS. 9A-9B, or a combination thereof. Though sixteen subarrays are shown in FIG. 11, memory device 1100 can have more or fewer than sixteen subarrays with an arrangement of plate line selects and plate line drivers adjusted according to the number of subarrays. Memory device 1100 can be, but is not limited to, a FeRAM. Memory device 1100 can be implemented in a variety of electronic devices.

Each subarray of subarrays 1142-0, 1142-1, 1142-2 . . . 1142-13, 1142-14, and 1142-15 of memory device 1100 can include an array of memory cells 1117 (single labels being used to show the components of a memory cell for ease of presentation) arranged in rows and columns, where each row is an access line and each column is a data line. Memory device 1100 can include access lines WL<0> . . . . WL<N−1> and data lines DL<0> . . . . DL<M−1>, where each memory cell is coupled to one access line of access lines WL<0> . . . . WL<N−1> and one digit line of DL<0> . . . DL<M−1>. Each memory cell 1117 can include a transistor 1103 having a gate coupled to a given access line, a drain/source of transistor 1103 coupled to a given data line, and a drain/source of transistor 1103 coupled to a plate of a capacitor 1108 of memory cell 1117. Capacitor 1108 can be a ferroelectric device with ferrroelectric material as the material between two electrode plates. Capacitor 1108 of memory cell 1117 can be structured on and extending vertically from its corresponding transistor 1103 with the associated WL and DL to the transistor 1103 structured at a level with transisitor 1103 below the vertical level of capacitor 1108.

Transistor 1103 operates as an access device to memory cell 1117 and capacitor 1108 operates as the data storage component of memory cell 1117, with a plate of capacitor 1108 coupled to a PL<j> assigned to the jth subarray of subarrays 1142-0, 1142-1, 1142-2 . . . 1142-13, 1142-14, and 1142-15 of memory device 1100. In various embodiments, the plate of capacitor 1108 coupled to a PL<j> can be structured as the top plate of capacitor 1108. With each capacitor in a subarrary <j> coupled to the same PL<j>, the subarrary <j> can be structured with a common plate to the capacitors 1108 of subarrary <j>. For simplicity and ease of discussion, the array is shown in only two dimensions, but the array can be extended into the third dimension.

Memory device 1100 includes plate drivers 1145-0, 1145-1, 1145-2 . . . 1145-13, 1145-14, 1145-15. For each N=0, 1, 2 . . . 13, 14, and 15, plate driver 1145-N (PLDRV<N>) is coupled to subarrary <N> providing a signal on PL<N> to the plate for subarrary <N> to select or unselect the PL<N> for activation of a selected plate of the subarrarys.

Data lines from each subarray <N> can be coupled to a digit line mutliplexer (DLMUX) 1151. DLMUX 1151 can be coupled to sense amplifiers 1150 to read and write to memory cells 1117 of subarrays 1142-0, 1142-1, 1142-2 . . . 1142-13, 1142-14, and 1142-15. The data lines can be grouped with respect to the subarrarys. For example, memory cells 1117 of subarray 1142-0 can be coupled to data lines DL<0> . . . . DL<1*M/16> and memory cells 1117 of subarray 1142-15 can be coupled to data lines DL<15*M/16> . . . . DL<M−1>. With M=64, each of subarrays 1142-0, 1142-1, 1142-2 . . . 1142-13, 1142-14, and 1142-15 corresponds to four data lines for each of the sixteen subarrays.

Memory device 1100 can be implemented as an IC within a package that includes pins for receiving supply voltages (e.g., to provide the drain/source and gate voltages for the transistors 1103) and signals (including data, address, and control signals). FIG. 11 depicts memory device 1100 in simplified form to illustrate basic structural components, omitting many details of the memory cells 1117 and associated access lines WL<0> . . . . WL<N−1> and data lines DL<0> . . . . DL<M−1> as well as the peripheral circuitry. For example, memory device 1100 can include further peripheral circuitry, such as a memory control unit that controls the memory operations based on control signals (provided, e.g., by an external processor), additional input/output circuitry, etc. Details of such peripheral circuitry are generally known to those of ordinary skill in the art and not further discussed herein.

In two-dimensional (2D) memory arrays, the rows of access lines WL<0> . . . . WL<N−1> and columns of data lines DL<0> . . . . DL<M−1> of memory cells 1117 are arranged along a single horizontal plane (i.e., a plane parallel to the layers) of the semiconductor substrate, e.g., in a rectangular lattice with mutually perpendicular horizontal access lines and data lines. In 3D memory arrays, the memory cells 1117 can be arranged in a 3D lattice that encompasses multiple vertically stacked horizontal planes corresponding to multiple device tiers of a multi-tier substrate assembly, with each device tier including multiple parallel rows of memory cells 1117 whose transistor gate terminals are connected by horizontal access lines such as access lines WL<0> . . . WL<N−1>. A “device tier,” as used herein, can include multiple layers (or levels) of materials, but forms the components of memory devices of a single horizontal tier of memory cells. Data lines such as data lines DL<0> . . . . DL<M−1> extend vertically through all or at least a vertical portion of the multi-tier structure, and each of the data lines DL<0> . . . . DL<M−1>connects to the transistor drain/source terminals of respective vertical columns of associated memory cells 1117 at the multiple device tiers. A 3D configuration of memory cells enables further increases in bit density compared with 2D arrays.

Example embodiments of devices and methods, in accordance with the teachings herein, are described in the following.

An example memory device 1 can comprise a first memory cell having a first top electrode separated from a first bottom electrode by a first ferroelectric region; a second memory cell having a second top electrode separated from a second bottom electrode by a second ferroelectric region; and a low-k dielectric material separating the first bottom electrode from the second bottom electrode.

An example memory device 2 can include features of example memory device 1 and can include electrode material of the first top electrode, the first bottom electrode, the second top electrode, or the second bottom electrode to include one or more of titanium, titanium nitride, or tungsten nitride.

An example memory device 3 can include features of any of the preceding example memory devices and can include ferroelectric material of the first ferroelectric region or the second ferroelectric region including hafnium oxide, zirconium oxide, or a combination of hafnium oxide and zirconium oxide.

An example memory device 4 can include features of any of the preceding example memory devices and can include the low-k dielectric material to include one or more of silicon oxide, silicon oxycarbide, fluorine doped silicon glass, or porous silicon oxide.

An example memory device 5 can include features of any of the preceding example memory devices and can include a plate coupled to the first top electrode and to the second top electrode.

An example memory device 6 can include features of example memory device 5 and any of the preceding example memory devices and can include the low-k dielectric material structured to: separate the first top electrode from the second top electrode; contact the first bottom electrode and the second bottom electrode at a vertical level below the first top electrode and the second top electrode; and extend from the vertical level at which the low-k dielectric material contacts the first bottom electrode and the second bottom electrode to the plate.

An example memory device 7 can include features of example memory device 5 and any of the preceding example memory devices and can include the first top electrode and the second top electrode being configured as a single continuous electrode located on and extending vertically from the low-k dielectric material to contact the plate.

An example memory device 8 can include features of example memory device 5 and any of the preceding example memory devices and can include the memory device including a leaker on and contacting the first bottom electrode and located under and coupled to the plate.

In an example memory device 9, any of the memory devices of example memory devices 1 to 8 may include memory devices incorporated into an electronic apparatus further comprising a host processor and a communication bus extending between the host processor and the memory device.

In an example memory device 10, any of the memory devices of example memory devices 1 to 9 may be modified to include any structure presented in another of example memory device 1 to 9.

In an example memory device 11, any apparatus associated with the memory devices of example memory devices 1 to 10 may further include a machine-readable storage device configured to store instructions as a physical state, wherein the instructions may be used to perform one or more operations of the apparatus.

In an example memory device 12, any of the memory devices of example memory devices 1 to 11 may be operated in accordance with any of the below example methods 1 to 9.

An example memory device 13 can comprise access lines, digit lines, and an array of memory cells. Each memory cell has an access transistor coupled to one of the access lines and has a storage structure coupled to one of the digit lines via the access transistor. The storage structure includes a top electrode separated from a bottom electrode by a ferroelectric region, where the bottom electrode is separated from a bottom electrode of an adjacent memory cell by a low-k dielectric material.

An example memory device 14 can include features of example memory device 13 and can include each memory cell being positioned within a container structure with three adjacent memory cells.

An example memory device 15 can include features of example memory device 14 and any features of the preceding example memory devices 13 to 14 and can include the array having multiple container structures separated by isolation dielectrics, each container structure containing four memory cells adjacent to each other with bottom electrodes of storage structures of the adjacent memory cells separated by the low-k dielectric material.

An example memory device 16 can include features of any of the preceding example memory devices 13 to 15 and can include the low-k dielectric material separating the ferroelectric region from a ferroelectric region of the adjacent memory cell and separating the top electrode from a top electrode of the adjacent memory cell.

An example memory device 17 can include features of example memory device 16 and any of the preceding example memory devices 13 to 16 and can include the low-k material extending from a bottom level of the bottom electrode to a plate positioned on a top surface of the top electrode and a top surface of the top electrode of the adjacent memory cell.

An example memory device 18 can include features of any of the preceding example memory devices 13 to 17 and can include the low-k dielectric material separating the ferroelectric region from a ferroelectric region of the adjacent memory cell; the top electrode is a top electrode of the adjacent memory cell; and the top electrode is positioned on the low-k dielectric material.

An example memory device 19 can include features of any of the preceding example memory devices 13 to 18 and can include the low-k dielectric material separating the bottom electrode from the bottom electrode of the adjacent memory cell by a distance equal to or less than about ten nanometers.

In an example memory device 20, any of the memory devices of example memory devices 13 to 19 may include the memory devices incorporated into an electronic apparatus further comprising a host processor and a communication bus extending between the host processor and the memory device.

In an example memory device 21, any of the memory devices of example memory devices 13 to 20 may be modified to include any structure presented in another of example memory device 13 to 20.

In an example memory device 22, any apparatus associated with the memory devices of example memory devices 13 to 21 may further include a machine-readable storage device configured to store instructions as a physical state, wherein the instructions may be used to perform one or more operations of the apparatus.

In an example memory device 23, any of the memory devices of example memory devices 13 to 22 may be operated in accordance with any of the below example methods 1 to 9.

An example method 1 of forming a memory device can comprise forming a first memory cell having a first top electrode separated from a first bottom electrode by a first ferroelectric region;

forming a second memory cell having a second top electrode separated from a second bottom electrode by a second ferroelectric region; and forming a low-k dielectric material separating the first bottom electrode from the second bottom electrode.

An example method 2 of forming a memory device can include features of example method 1 of forming a memory device and can include forming a continuous conductive material for the first bottom electrode and the second bottom electrode on a surface above a region for access transistors for the first memory cell and the second memory cell; forming ferroelectric material, for the first ferroelectric region and the second ferroelectric region, on the continuous conductive material; forming a second conductive material, for the first top electrode and the second top electrode, on the ferroelectric material; removing portions of the ferroelectric material, portions of the continuous conductive material, and portions of the second conductive material, forming an opening from above a level for a top surface of the ferroelectric material to the surface above the region for access transistors; and forming the low-k dielectric material using the opening to separate the first bottom electrode from the second bottom electrode.

An example method 3 of forming a memory device can include features of any of the preceding example methods of forming a memory device and can include removing portions of the ferroelectric material, portions of the continuous conductive material, and portions of the second conductive material including etching to separate the first bottom electrode and the second bottom electrode and bottom electrodes of other adjacent cells being formed in a first container structure containing the first memory cell and the second memory cell such that the etching is selective to substantially maintain an isolation dielectric between the first container structure and an adjacent container structure for forming memory cells.

An example method 4 of forming a memory device can include features of example method 2 of forming a memory device and any of the preceding example methods of forming a memory device and can include forming the low-k dielectric material using the opening to include: filling the opening with the low-k dielectric material, including forming the low-k dielectric material on a photoresist formed on the second conductive material, the photoresist formed before removing the portions of the second conductive material; removing the photoresist while maintaining the low-k dielectric material filling the opening, forming a first open region between the low-k dielectric material and the second conductive material and a second open region between the low-k dielectric material and the second conductive material; and forming the first top electrode in the first open region and forming the second top electrode in the second open region such that the low-k dielectric material separates the first top electrode from the second top electrode, the first ferroelectric region from the second ferroelectric region, and the first bottom electrode from the second bottom electrode.

An example method 5 of forming a memory device can include features of example method 2 of forming a memory device and any of the preceding example methods of forming a memory device and can include forming the low-k dielectric material using the opening to include: conformally forming the low-k dielectric material in the opening including forming the low-k material on the second conductive material; removing the low-k dielectric material leaving a portion of the low-k dielectric material such that the low-k dielectric material is recessed below a bottom of the second conductive material and is positioned between the first bottom electrode and the second bottom electrode; and forming a third conductive material on the recessed low-k dielectric material and on the second conductive material, extending from the recessed low-k dielectric material to a top level of the ferroelectric material for the first ferroelectric region and the second ferroelectric region, the third conductive material arranged as the first top electrode and the second top electrode.

In an example method 6 of forming a memory device, any of the example methods 1 to 5 of forming a memory device may be performed in forming an electronic apparatus further comprising a host processor and a communication bus extending between the host processor and the memory device.

In an example method 7 of forming a memory device, any of the example methods 1 to 6 of forming a memory device may be modified to include operations set forth in any other of example methods 1 to 6 of forming a memory device.

In an example method 8 of forming a memory device, any of the example methods 1 to 7 of forming a memory device may be implemented at least in part through use of instructions stored as a physical state in one or more machine-readable storage devices.

An example method 9 of forming a memory device can include features of any of the preceding example methods 1 to 8 of forming a memory device and can include performing functions associated with any features of example memory devices 1 to 12 and example memory devices 13 to 23.

An example machine-readable storage device storing instructions, that when executed by one or more processors, cause a machine to perform operations, can comprise instructions to perform functions associated with any features of example memory devices 1 to 12 or example memory devices 13 to 23 or perform methods associated with any features of example methods 1 to 9 of forming a memory device.

Although specific embodiments have been illustrated and described herein, it will be appreciated by those of ordinary skill in the art that any arrangement that is calculated to achieve the same purpose can be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
a first memory cell having a first top electrode separated from a first bottom electrode by a first ferroelectric region;
a second memory cell having a second top electrode separated from a second bottom electrode by a second ferroelectric region; and
a low-k dielectric material separating the first bottom electrode from the second bottom electrode.

2. The memory device of claim 1, wherein electrode material of the first top electrode, the first bottom electrode, the second top electrode, or the second bottom electrode includes one or more of titanium, titanium nitride, or tungsten nitride.

3. The memory device of claim 1, wherein ferroelectric material of the first ferroelectric region or the second ferroelectric region includes hafnium oxide, zirconium oxide, or a combination of hafnium oxide and zirconium oxide.

4. The memory device of claim 1, wherein the low-k dielectric material includes one or more of silicon oxide, silicon oxycarbide, fluorine doped silicon glass, or porous silicon oxide.

5. The memory device of claim 1, wherein the memory device includes a plate coupled to the first top electrode and to the second top electrode.

6. The memory device of claim 5, wherein the low-k dielectric material:
separates the first top electrode from the second top electrode;
contacts the first bottom electrode and the second bottom electrode at a vertical level below the first top electrode and the second top electrode; and
extends from the vertical level at which the low-k dielectric material contacts the first bottom electrode and the second bottom electrode to the plate.

7. The memory device of claim 5, wherein the first top electrode and the second top electrode are configured as a single continuous electrode located on and extending vertically from the low-k dielectric material to contact the plate.

8. The memory device of claim 5, wherein the memory device includes a leaker on and contacting the first bottom electrode and located under and coupled to the plate.

9. A memory device comprising:
access lines;
digit lines; and
an array of memory cells, each memory cell having an access transistor coupled to one of the access lines and having a storage structure coupled to one of the digit lines via the access transistor, the storage structure including a top electrode separated from a bottom electrode by a ferroelectric region, the bottom electrode separated from a bottom electrode of an adjacent memory cell by a low-k dielectric material.

10. The memory device of claim 9, wherein each memory cell is positioned within a container structure with three adjacent memory cells.

11. The memory device of claim 10, wherein the array has multiple container structures separated by isolation dielectrics, each container structure containing four memory cells adjacent to each other with bottom electrodes of storage structures of the adjacent memory cells separated by the low-k dielectric material.

12. The memory device of claim 9, wherein the low-k dielectric material separates the ferroelectric region from a ferroelectric region of the adjacent memory cell and separates the top electrode from a top electrode of the adjacent memory cell.

13. The memory device of claim 12, wherein the low-k dielectric material extends from a bottom level of the bottom electrode to a plate positioned on a top surface of the top electrode and a top surface of the top electrode of the adjacent memory cell.

14. The memory device of claim 9, wherein:
the low-k dielectric material separates the ferroelectric region from a ferroelectric region of the adjacent memory cell;
the top electrode is a top electrode of the adjacent memory cell; and
the top electrode is positioned on the low-k dielectric material.

15. The memory device of claim 9, wherein the low-k dielectric material separates the bottom electrode from the bottom electrode of the adjacent memory cell by a distance equal to or less than about ten nanometers.

16. A method of forming a memory device, the method comprising:
forming a first memory cell having a first top electrode separated from a first bottom electrode by a first ferroelectric region;
forming a second memory cell having a second top electrode separated from a second bottom electrode by a second ferroelectric region; and
forming a low-k dielectric material separating the first bottom electrode from the second bottom electrode.

17. The method of claim 16, wherein the method includes
forming a continuous conductive material for the first bottom electrode and the second bottom electrode on a surface above a region for access transistors for the first memory cell and the second memory cell;
forming ferroelectric material, for the first ferroelectric region and the second ferroelectric region, on the continuous conductive material;
forming a second conductive material, for the first top electrode and the second top electrode, on the ferroelectric material;
removing portions of the ferroelectric material, portions of the continuous conductive material, and portions of the second conductive material, forming an opening from above a level for a top surface of the ferroelectric material to the surface above the region for access transistors; and
forming the low-k dielectric material using the opening to separate the first bottom electrode from the second bottom electrode.

18. The method of claim 17, wherein removing portions of the ferroelectric material, portions of the continuous conductive material, and portions of the second conductive material includes etching to separate the first bottom electrode and the second bottom electrode and bottom electrodes of other adjacent cells being formed in a first container structure containing the first memory cell and the second memory cell such that the etching is selective to substantially maintain an isolation dielectric between the first container structure and an adjacent container structure for forming memory cells.

19. The method of claim 17, wherein forming the low-k dielectric material using the opening includes:
filling the opening with the low-k dielectric material, including forming the low-k dielectric material on a photoresist formed on the second conductive material, the photoresist formed before removing the portions of the second conductive material;
removing the photoresist while maintaining the low-k dielectric material filling the opening, forming a first open region between the low-k dielectric material and the second conductive material and a second open region between the low-k dielectric material and the second conductive material; and
forming the first top electrode in the first open region and forming the second top electrode in the second open region such that the low-k dielectric material separates the first top electrode from the second top electrode, the first ferroelectric region from the second ferroelectric region, and the first bottom electrode from the second bottom electrode.

20. The method of claim 17, wherein forming the low-k dielectric material using the opening includes:
conformally forming the low-k dielectric material in the opening including forming the low-k dielectric material on the second conductive material;
removing the low-k dielectric material leaving a portion of the low-k dielectric material such that the low-k dielectric material is recessed below a bottom of the second conductive material and is positioned between the first bottom electrode and the second bottom electrode; and
forming a third conductive material on the recessed low-k dielectric material and on the second conductive material, extending from the recessed low-k dielectric material to a top level of the ferroelectric material for the first ferroelectric region and the second ferroelectric region, the third conductive material arranged as the first top electrode and the second top electrode.
